(19) United States
(12) Patent Application Publication
(10) Pub. No.: US 2026/0280760 A1
(43) Pub. Date: Sep. 17, 2026

(54) Communication Method, Communication Apparatus, and Computer-Readable Storage Medium

(71) Applicant: HUAWEI TECHNOLOGIES CO., LTD., Shenzhen (CN)

(72) Inventors: Xianbin Wang, Hangzhou (CN); Huazi Zhang, Hangzhou (CN); Jiajie Tong, Hangzhou (CN); Kangjian Qin, Hangzhou (CN); Ke Liu, Hangzhou (CN); Jun Wang, Hangzhou (CN); Wen Tong, Ottawa (CA)

(73) Assignee: HUAWEI TECHNOLOGIES CO., LTD., Shenzhen (CN)

(21) Appl. No.: 19/676,145

(22) Filed: May 13, 2026

Related U.S. Application Data
(63) Continuation of application No. PCT/CN2024/127502, filed on Oct. 25, 2024.

(30) Foreign Application Priority Data
Nov. 14, 2023 (CN) 202311524275.0

(51) Int. Cl. H04L 1/00; H03M 13/13

(52) U.S. Cl. CPC H04L 1/0057; H03M 13/13; H04L 1/0007

(57) ABSTRACT

A communication method includes: determining a pre-frozen bit subchannel set based on a reliability sequence of length N₂; determining a first information bit subchannel set based on a first reliability subsequence of length N in the reliability sequence; determining a second information bit subchannel set based on the reliability sequence and the pre-frozen bit subchannel set; determining, based on a second bit subchannel subset in the second information bit subchannel set, a corresponding first bit subchannel subset in the first information bit subchannel set; determining a bit sequence based on the first bit subchannel subset and the second bit subchannel subset; and performing polar encoding on the bit sequence to obtain an encoded result.

### CROSS-REFERENCE TO RELATED APPLICATIONS

This is a continuation of International Patent Application No. PCT/CN2024/127502 filed on Oct. 25, 2024, which claims priority to Chinese Patent Application No. 202311524275.0 filed on Nov. 14, 2023, which are hereby incorporated by reference in their entireties.

### TECHNICAL FIELD

Embodiments of this disclosure relate to the communication field, and more specifically, to a communication method, a communication apparatus, and a computer-readable storage medium.

### BACKGROUND

Polar codes are the first channel coding scheme strictly proved to achieve the Shannon channel capacity. They offer excellent error correction performance with low decoding complexity, and have been adopted by the 3rd Generation Partnership Project (3GPP) as the coding scheme for control channels in 5th generation (5G) enhanced mobile broadband (eMBB) scenarios.

### SUMMARY

Embodiments of this disclosure provide a communication method based on polar coding. The method involves determining a pre-frozen bit subchannel set and further identifying a first bit subchannel subset and a second bit subchannel subset that have a specific correspondence.

According to a first aspect of this disclosure, a communication method is provided. The method includes: determining a pre-frozen bit subchannel set based on a reliability sequence of length N₂, where a quantity of elements in the pre-frozen bit subchannel set is greater than or equal to 0, and N₂ is a positive integer; determining a first information bit subchannel set based on a first reliability subsequence of length N in the reliability sequence, where N is a positive integer and N is less than N₂; determining a second information bit subchannel set based on the reliability sequence and the pre-frozen bit subchannel set; determining, based on a second bit subchannel subset in the second information bit subchannel set, a corresponding first bit subchannel subset in the first information bit subchannel set; determining a bit sequence based on the first bit subchannel subset and the second bit subchannel subset; and performing polar encoding on the bit sequence to obtain an encoded result.

In this manner, in embodiments of this disclosure, the pre-frozen bit subchannel set may be determined, and the second bit subchannel subset and the corresponding first bit subchannel subset may be determined based on the pre-frozen bit subchannel set. In this way, transmission performance can be improved in this solution.

In some implementations, determining the pre-frozen bit subchannel set based on the reliability sequence of length N₂ includes: determining, from subchannel indices 0 to N−1, a subchannel set with N₁ elements, where N₁ is a positive integer less than N, and N₂=N×2; determining, based on the reliability sequence and the subchannel set, a second reliability subsequence of length N+N₁; and determining the pre-frozen bit subchannel set based on the second reliability subsequence. In this way, in embodiments of this disclosure, the pre-frozen bit subchannel set is determined based on the subchannel set with N₁ (N₁ subchannel sequence numbers) elements, and then an information bit set can be determined. In this way, fine-grained and flexible encoding for transmission can be implemented.

In some implementations, determining the pre-frozen bit subchannel set based on the second reliability subsequence may include: determining, based on the second reliability subsequence and a predetermined threshold, the pre-frozen bit subchannel set.

In some implementations, determining, based on the second reliability subsequence and the predetermined threshold, the pre-frozen bit subchannel set includes: obtaining K subchannel indices with high reliability based on the second reliability subsequence, where K indicates a quantity of bits to be encoded, and K is a positive integer less than or equal to N; and determining the pre-frozen bit subchannel set from the subchannel set based on the K subchannel indices and the threshold. In this way, the pre-frozen bit subchannel set can be determined based on a configurable threshold, so that implementation of the solution is more flexible, and encoding is more flexible.

In some implementations, determining the pre-frozen bit subchannel set from the subchannel set based on the K subchannel indices and the threshold includes: if a first subchannel index among the K subchannel indices is less than or does not exceed (is less than or equal to) the threshold, marking an unmarked subchannel with highest reliability in the subchannel set as a candidate information bit; and after completing comparison for each of the K subchannel indices, determining a set of unmarked subchannels in the subchannel set as the pre-frozen bit subchannel set. In this way, the candidate information bit can be determined based on the threshold, and then the pre-frozen bit subchannel set is determined. This can reduce a quantity of information bits in the subchannel set and improve performance when a small quantity of retransmissions are performed.

In some implementations, determining the subchannel set with N₁ elements includes: obtaining N₁ subchannel indices in descending order from the subchannel indices 0 to N−1 arranged in a natural order to determine the subchannel set with N₁ elements; or obtaining N₁ subchannel indices in a reverse order based on an interleaved order corresponding to the subchannel indices 0 to N−1 to determine the subchannel set with N₁ elements. In this way, the subchannel set with N₁ elements can be determined based on subchannels that are more likely to be transmitted, that is, N₁ subchannel indices. In this way, a small quantity of retransmissions and a large quantity of retransmissions can be considered, and performance can be ensured.

Optionally, N₁ subchannel indices with larger subchannel indices may be extracted from the subchannel indices 0 to N−1, to form the subchannel set with N₁ elements.

In some implementations, a value of N₁ is predetermined, for example, N₁=N/2 or N=N/4. In this way, complexity can be reduced. In some other implementations, the value of N₁ is determined based on a system-scheduled resource. In this way, flexibility can be improved.

In some implementations, the method further includes: determining the threshold based on K, N, and N₁, where K indicates the quantity of bits to be encoded, and K is a positive integer less than or equal to N.

Optionally, determining the threshold based on a ratio of K to (N+N₁) includes: in response to K/(N+N₁) being less than or equal to 130/512, determining that the threshold is equal to N; or in response to K/(N+N₁) being greater than 130/512, determining that the threshold is equal to └63/64×N┘. In this manner, the threshold can be configured, and flexibility of this solution can be improved by configuring the threshold.

In some implementations, determining, based on the reliability sequence and the subchannel set, the second reliability subsequence of length N+N₁ includes: extracting, from the reliability sequence, the second reliability subsequence of length N+N₁, where N+N₁ subchannel indices corresponding to the second reliability subsequence include N subchannel indices corresponding to the first reliability subsequence and the Ni subchannel indices in the subchannel set.

In some implementations, determining the first information bit subchannel set based on the first reliability subsequence of length N in the reliability sequence includes: determining, based on the first reliability subsequence, the K subchannel indices with high reliability to obtain the first information bit subchannel set. In this manner, K subchannels with high reliability can be used as information bit subchannels for transmitting information bits. In this way, a transmission success rate of the information bits can be improved, thereby ensuring communication performance.

Optionally, determining the first information bit subchannel set based on the first reliability subsequence of length N in the reliability sequence includes: determining, based on the first reliability subsequence, N-K subchannel indices as N-K frozen bits, and further determining remaining K subchannel indices other than the N-K frozen bits to obtain the first information bit subchannel set.

In some implementations, determining the second information bit subchannel set based on the reliability sequence and the pre-frozen bit subchannel set includes: determining, based on the reliability sequence, K subchannel indices with high reliability that do not belong to the pre-frozen bit subchannel set to obtain the second information bit subchannel set. In this manner, subchannel indices in the pre-frozen bit subchannel set can be excluded, to avoid using subchannels in the pre-frozen bit subchannel set as information bits. In this way, the information bits can be prevented from being placed on subchannels with low reliability.

In some implementations, determining, based on the second bit subchannel subset in the second information bit subchannel set, the corresponding first bit subchannel subset in the first information bit subchannel set includes: obtaining the second bit subchannel subset based on a subchannel index that is less than (or less than or equal to) N in the second information bit subchannel set; and determining, based on a quantity of elements in the second bit subchannel subset, a same quantity of subchannel indices with low reliability in the first information bit subchannel set to obtain the first bit subchannel subset.

In some implementations, one or more subchannel indices in the second bit subchannel subset correspond to one or more subchannel indices in the first bit subchannel subset. For example, an information bit at a corresponding subchannel in the second bit subchannel subset may be determined based on an information bit at a subchannel in the first bit subchannel subset. For example, information bits at corresponding subchannels may have a copy relationship. In this manner, a decoding success rate can be improved, and better decoding performance can be ensured.

In some implementations, the bit sequence includes an information bit at each subchannel in the second bit subchannel subset, and the information bit at each subchannel in the second bit subchannel subset is the same as an information bit at each subchannel in the corresponding first bit subchannel subset.

In some implementations, the method further includes: performing interleaving based on the encoded result to obtain an interleaved bit sequence; and outputting one or more bits from the interleaved bit sequence. For example, a quantity of the one or more bits may be determined based on a configured retransmission resource. For example, the one or more bits may be determined from the interleaved bit sequence in a reverse order. In this manner, transmission performance can be further ensured through interleaving, for example, sub-block interleaving.

According to a second aspect of this disclosure, a communication method is provided. The method includes: receiving a symbol sequence; determining a pre-frozen bit subchannel set based on a reliability sequence of length N₂, where a quantity of elements in the pre-frozen bit subchannel set is greater than or equal to 0, and N₂ is a positive integer; determining a first information bit subchannel set based on a first reliability subsequence of length N in the reliability sequence, where N is a positive integer and N is less than N₂; determining a second information bit subchannel set based on the reliability sequence and the pre-frozen bit subchannel set; determining, based on a second bit subchannel subset in the second information bit subchannel set, a corresponding first bit subchannel subset in the first information bit subchannel set; and decoding the received symbol sequence based on the first bit subchannel subset and the second bit subchannel subset to obtain a bit sequence.

In some implementations, obtaining the bit sequence includes: performing polar decoding on a de-interleaved symbol sequence to obtain the bit sequence.

In some implementations, the method further includes: padding the symbol sequence to obtain a padded symbol sequence; and performing de-interleaving based on the padded symbol sequence to obtain the de-interleaved symbol sequence.

In some implementations, determining the pre-frozen bit subchannel set based on the reliability sequence of length N₂ includes: determining, from subchannel indices 0 to N−1, a subchannel set with N₁ elements, where N₁ is a positive integer less than N, and N₂=N×2; determining, based on the reliability sequence and the subchannel set, a second reliability subsequence of length N+N₁; and determining the pre-frozen bit subchannel set based on the second reliability subsequence.

In some implementations, determining the pre-frozen bit subchannel set based on the second reliability subsequence may include: determining, based on the second reliability subsequence and a predetermined threshold, the pre-frozen bit subchannel set.

In some implementations, determining, based on the second reliability subsequence and the predetermined threshold, the pre-frozen bit subchannel set includes: obtaining K subchannel indices with high reliability based on the second reliability subsequence, where K indicates a quantity of bits to be encoded, and K is a positive integer less than or equal to N; and determining the pre-frozen bit subchannel set from the subchannel set based on the K subchannel indices and the threshold.

In some implementations, determining the pre-frozen bit subchannel set from the subchannel set based on the K subchannel indices and the threshold includes: when a first subchannel index among the K subchannel indices is less than or does not exceed the threshold, marking an unmarked subchannel with highest reliability in the subchannel set as a candidate information bit; and after completing comparison for each of the K subchannel indices, determining a set of unmarked subchannels in the subchannel set as the pre-frozen bit subchannel set.

In some implementations, determining the subchannel set with N₁ elements includes: obtaining N₁ subchannel indices in descending order from the subchannel indices 0 to N−1 arranged in a natural order to determine the subchannel set with N₁ elements; or obtaining N₁ subchannel indices in a reverse order based on an interleaved order corresponding to the subchannel indices 0 to N−1 to determine the subchannel set with N₁ elements.

In some implementations, a value of N₁ is predetermined, or is determined based on a system-scheduled resource.

In some implementations, the method further includes: determining the threshold based on K, N, and N₁, where K indicates the quantity of bits to be encoded, and K is a positive integer less than or equal to N. For example, the threshold may be determined based on a ratio of K to (N+N₁).

In some implementations, determining the threshold based on the ratio of K to (N+N₁) includes: in response to K/(N+N₁) being less than or equal to 130/512, determining that the threshold is equal to N; or in response to K/(N+N₁) being greater than 130/512, determining that the threshold is equal to └63/64×N┘.

In some implementations, determining, based on the reliability sequence and the subchannel set, the second reliability subsequence of length N+N₁ includes: extracting, from the reliability sequence, the second reliability subsequence of length N+N₁, where N+N₁ subchannel indices corresponding to the second reliability subsequence include N subchannel indices corresponding to the first reliability subsequence and the N₁ subchannel indices in the subchannel set.

In some implementations, determining the first information bit subchannel set based on the first reliability subsequence of length N in the reliability sequence includes: determining, based on the first reliability subsequence, the K subchannel indices with high reliability to obtain the first information bit subchannel set.

In some implementations, determining the second information bit subchannel set based on the reliability sequence and the pre-frozen bit subchannel set includes: determining, based on the reliability sequence, K subchannel indices with high reliability that do not belong to the pre-frozen bit subchannel set to obtain the second information bit subchannel set.

In some implementations, determining, based on the second bit subchannel subset in the second information bit subchannel set, the corresponding first bit subchannel subset in the first information bit subchannel set includes: obtaining the second bit subchannel subset based on a subchannel index that is less than N in the second information bit subchannel set; and determining, based on a quantity of elements in the second bit subchannel subset, a same quantity of subchannel indices with low reliability in the first information bit subchannel set to obtain the first bit subchannel subset.

In some implementations, one or more subchannel indices in the second bit subchannel subset are in a one-to-one correspondence with one or more subchannel indices in the first bit subchannel subset.

In some implementations, the bit sequence includes an information bit at each subchannel in the second bit subchannel subset, and the information bit at each subchannel in the second bit subchannel subset is the same as an information bit at each subchannel in the corresponding first bit subchannel subset.

In some implementations, the method further includes: receiving an initial transmission symbol sequence; and determining, based on the initial transmission symbol sequence, the information bit at each subchannel in the first bit subchannel subset.

It should be noted that some implementations and beneficial effects of the first aspect are also applicable to the second aspect. For brevity, details are not repeated herein again.

According to a third aspect of this disclosure, a communication apparatus is provided, including components configured to perform an operation of the method according to the first aspect or any implementation of the first aspect. Optionally, the components may be implemented as units, modules, or the like.

According to a fourth aspect of this disclosure, a communication apparatus is provided, including components configured to perform an operation of the method according to the second aspect or any implementation of the second aspect. Optionally, the components may be implemented as units, modules, or the like.

According to a fifth aspect of this disclosure, a communication apparatus is provided, including a transceiver, a processor, and a memory. The memory stores instructions executed by the processor. When the instructions are executed by the processor, the communication apparatus is enabled to perform an operation of the method according to the first aspect or any implementation of the first aspect.

According to a sixth aspect of this disclosure, a communication apparatus is provided, including a transceiver, a processor, and a memory. The memory stores instructions executed by the processor. When the instructions are executed by the processor, the communication apparatus is enabled to perform an operation of the method according to the second aspect or any implementation of the second aspect.

According to a seventh aspect of this disclosure, a communication system is provided. The communication system includes the communication apparatus according to the third aspect or the fifth aspect, and further includes the communication apparatus according to the fourth aspect or the sixth aspect.

According to an eighth aspect of this disclosure, a computer-readable storage medium, for example, a non-transitory computer-readable storage medium, is provided. The computer-readable storage medium stores a computer program; and when the computer program is executed by a processor, an operation of the method according to any one of the first aspect or the second aspect or the implementations of the first aspect or the second aspect is implemented.

According to a ninth aspect of this disclosure, a chip or a chip system is provided. The chip or the chip system includes a processing circuit, configured to perform an operation of the method according to any one of the first aspect or the second aspect or the implementations of the first aspect or the second aspect.

According to a tenth aspect of this disclosure, a computer program or a computer program product is provided. The computer program or the computer program product is tangibly stored on a computer-readable medium and includes computer-executable instructions. When the computer-executable instructions are executed, a device is enabled to implement an operation of the method according to any one of the first aspect or the second aspect or the implementations of the first aspect or the second aspect.

It should be noted that some embodiments and beneficial effects of the foregoing method aspects are also applicable to an apparatus aspect, a user equipment aspect, a network device aspect, a computer-readable storage medium aspect, a chip or chip system aspect, or a computer program or computer program product aspect. For brevity, details are not described herein again.

### BRIEF DESCRIPTION OF DRAWINGS

The foregoing and other features, advantages, and aspects of embodiments of this disclosure become more apparent with reference to accompanying drawings and the following detailed description. In the accompanying drawings, same or similar reference numerals indicate same or similar elements.

FIG. 1 is a diagram of a communication system in which some embodiments of this disclosure may be implemented;

FIG. 2A is a diagram of processing between a transmit end and a receive end in a communication system;

FIG. 2B is a diagram of an 8×8 polar code with 8 input bits and 8 output bits;

FIG. 2C is a diagram of a polar code for incremental redundancy hybrid automatic repeat request (IR-HARQ);

FIG. 2D is a diagram of a polar code supporting self-decoding;

FIG. 2E shows a scenario in which a code is constructed based on M=2, and a retransmission scheduled coding length determined based on an actual retransmission resource M=8;

FIG. 2F shows a scenario in which a code is constructed based on M=8, and a retransmission scheduled coding length determined based on an actual retransmission resource M=2;

FIG. 3 is a flowchart of an example process according to some embodiments of this disclosure;

FIG. 4 is a diagram of an example of determining a second bit subchannel subset and a first bit subchannel subset according to some embodiments of this disclosure;

FIG. 5 is a diagram of an example process of a transmit end according to an embodiment of this disclosure;

FIG. 6 is a diagram of sub-block interleaving according to some embodiments of this disclosure;

FIG. 7 is a block diagram of an example communication apparatus according to some embodiments of this disclosure;

FIG. 8 is another block diagram of an example communication apparatus according to some embodiments of this disclosure; and

FIG. 9 is a block diagram of an example device that may be used to implement an embodiment of this disclosure.

### DESCRIPTION OF EMBODIMENTS

Embodiments of this disclosure are described in more detail in the following with reference to accompanying drawings. Although some embodiments of this disclosure are shown in the accompanying drawings, it should be understood that this disclosure can be implemented in various forms, and should not be construed as being limited to embodiments described herein, and instead, these embodiments are provided for a more thorough and complete understanding of this disclosure. It should be understood that the accompanying drawings and embodiments of this disclosure are merely used as examples and are not intended to limit the protection scope of this disclosure.

In the descriptions of embodiments of this disclosure, the term “including” and similar terms thereof shall be understood as non-exclusive inclusions, that is, “including but not limited to”. The term “based on” should be understood as “at least partially based on”. The term “one embodiment” or “some embodiments” should be understood as “at least one embodiment”. The terms “first”, “second”, and the like may indicate different or same objects, and are not intended to indicate a sequence. Other explicit and implicit definitions may also be included below.

Embodiments of this disclosure may be implemented according to any appropriate communication protocol, including but not limited to cellular communication protocols such as 3rd generation (3G), 4th generation (4G), 5G, and 6th generation (6G), a wireless local area network communication protocol such as The Institute of Electrical and Electronics Engineers (IEEE) 802.11, and/or any other protocols currently known or developed in the future.

The technical solutions in embodiments of this disclosure are applied to a communication system that complies with any appropriate communication protocol, for example, a narrowband Internet of things (NB-IoT) system, a Global System for Mobile Communications (GSM), an Enhanced Data Rate for GSM evolution (EDGE) system, a Universal Mobile Telecommunications Service (UMTS) system, a Long-Term Evolution (LTE) system, a wideband code-division multiple access (WCDMA) system, a code-division multiple access 2000 (CDMA2000) system, a time division-synchronization code division multiple access (TD-SCDMA) system, a frequency-division duplex (FDD) system, a time-division duplex (TDD) system, a 5G system or a New Radio (NR) system, a beyond 5G (B5G) system, a 6G communication system, a 7th generation (7G) communication system, and a public land mobile network (PLMN) system. It should be understood that the communication system may be applicable to a high frequency scenario (such as a millimeter wave scenario) or a low frequency scenario.

It should be understood that embodiments of this disclosure may be applied to any communication system in which a similar problem exists, for example, a wireless local area network (WLAN), a wired communication system, or another communication system that is to be developed in the future.

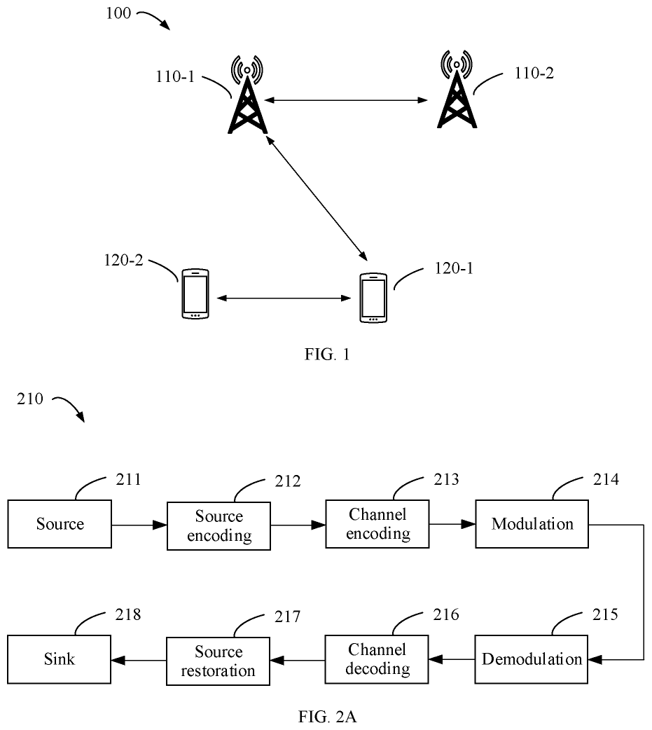

FIG. 1 is a diagram of a communication system 100 in which some embodiments of this disclosure may be implemented. As shown in FIG. 1, the communication system 100 may include a network device 110-1, a network device 110-2, a terminal device 120-1, and a terminal device 120-2. The network device 110-1 can provide a communication service for the terminal device 120-1.

The terminal device 120-1 and the terminal device 120-2 each may be referred to as or may be collectively referred to as a terminal device 120. The terminal device 120 may be user equipment (UE), a terminal, an access terminal, a terminal unit, a terminal station, a mobile station (MS), a remote station, a remote terminal, a mobile terminal, a wireless communication device, a terminal agent, terminal equipment, or the like. The terminal device 120 may alternatively be a communication chip possessing a communication module, or may be a vehicle with a communication function, a vehicle-mounted device (for example, a vehicle-mounted communication apparatus or a vehicle-mounted communication chip), or the like. The terminal device 120 may have a wireless transceiver function. The terminal device 120 can perform communication (for example, wireless communication) with one or more network devices in one or more communication systems, and accepts a network service provided by the network device. The network device herein includes but is not limited to the network device 110-1 shown in the figure.

The terminal device 120 may be a cellular phone, a cordless phone, a Session Initiation Protocol (SIP) phone, a wireless local loop (WLL) station, a personal digital assistant (PDA) device, a handheld device with a wireless communication function, a compute device, another processing device connected to a wireless modem, a vehicle-mounted device, a wearable device, a terminal apparatus in a future 5G network, a terminal apparatus in a PLMN network, or the like.

The terminal device 120 may be a mobile phone, a tablet computer, a computer with a wireless transceiver function, a virtual reality (VR) terminal, an augmented reality (AR) terminal, a wireless terminal in industrial control, a wireless terminal in self-driving, a wireless terminal in remote medical, a wireless terminal in a smart grid, a wireless terminal in transportation safety, a wireless terminal in a smart city, a wireless terminal in a smart home, or the like.

The terminal device 120 may be deployed on land, including an indoor terminal device, an outdoor terminal device, a handheld terminal device, or a vehicle-mounted terminal device; or the terminal device 120 may be deployed on water (for example, on a ship); or the terminal device 120 may be deployed in the air (for example, on a plane, a balloon, or a satellite).

The network device 110-1 and the network device 110-2 each may be referred to as or may be collectively referred to as a network device 110. The network device 110 may be an access network device (or referred to as an access website). The access network device is a device that provides a network access function, for example, a radio access network (RAN) base station (BS). The network device 110 may include a base station, or include a base station, a radio resource management device configured to control the base station, and the like. The base station may include a baseband unit (BBU) and a remote radio unit (RRU). The BBU and the RRU may be deployed in different places. For example, the RRU is remotely deployed in a heavy-traffic area, and the BBU is deployed in a central equipment room. Alternatively, the BBU and the RRU may be deployed in a same equipment room. Alternatively, the BBU and the RRU may be different components at a same rack. The network device 110 may include a relay station, an access point, a base station or an NR base station in a 5G network, a base station in a PLMN network, or the like. The network device 110 may be a wearable device or a vehicle-mounted device. Alternatively, the network device 110 may be a communication chip possessing a communication module.

The network device 110 includes but is not limited to: a NodeB (gNodeB, gNB) in 5G, an evolved NodeB (eNB or eNodeB) in an LTE system, a radio network controller (RNC), a radio controller in a cloud radio access network (CRAN) system, a base station controller (BSC), a home evolved NodeB (for example, home evolved NodeB, or home NodeB, HNB), a BBU, a transmitting and receiving point (TRP), a transmitting point (TP), a mobile switching center, a base station device in a future 5G network, an access network device in a future evolved PLMN network, a wearable device, or a vehicle-mounted device.

In some deployments, the network device 110 may include a central unit (CU) and a distributed unit (DU). The network device may further include an active antenna unit (AAU). The CU implements some functions of the network device, and the DU implements some other functions of the network device. For example, the CU is responsible for processing a non-real-time protocol and service, and implementing functions of a radio resource control (RRC) layer and a Packet Data Convergence Protocol (PDCP) layer. The DU is responsible for processing a physical layer protocol and a real-time service, and implements functions of a radio link control (RLC) layer, a media access control (MAC) layer, and a physical layer (PHY). The AAU implements some physical layer processing functions, radio frequency processing, and a function related to an active antenna. Information at the RRC layer is eventually converted into information at the PHY layer, or is converted from information at the PHY layer. Therefore, in this architecture, higher layer signaling such as RRC layer signaling may also be considered as being sent by the DU or sent by the DU and the AAU. It may be understood that the network device 110 may be a device including one or more of a CU node, a DU node, and an AAU node. In addition, the CU may be classified as a network device in a RAN, or the CU may be classified as a network device in a core network (CN). This is not limited in this disclosure. Examples of the network device include but are not limited to a NodeB (NodeB or NB), an evolved NodeB (eNodeB or eNB), a next-generation NodeB (gNB), a TRP, an RRU, a radio head (RH), a remote radio head (RRH), an integrated access and backhaul (IAB) node, and a low power node, for example, a femto node, a pico node, a reconfigurable intelligent surface (RIS), and a network-controlled repeater.

In addition, the network device 110 may be connected to a core network device, and the core network device may be configured to provide a core network service for the network device 110 and the terminal device 120. The core network device may correspond to different devices in different systems. For example, in 3G, the core network device may correspond to a serving General Packet Radio Service (GPRS) support node (SGSN) and/or a gateway GPRS support node (GGSN). In 4G, the core network device may correspond to a mobility management entity (MME) and/or a serving gateway (S-GW). In 5G, the core network device may correspond to an access and mobility management function (AMF), a session management function (SMF), or a user plane function (UPF).

It should be understood that a quantity of network devices 110 and a quantity of terminal devices 120 shown in FIG. 1 are merely examples. In an actual scenario, more or fewer network devices 110 and/or terminal devices 120 may be included.

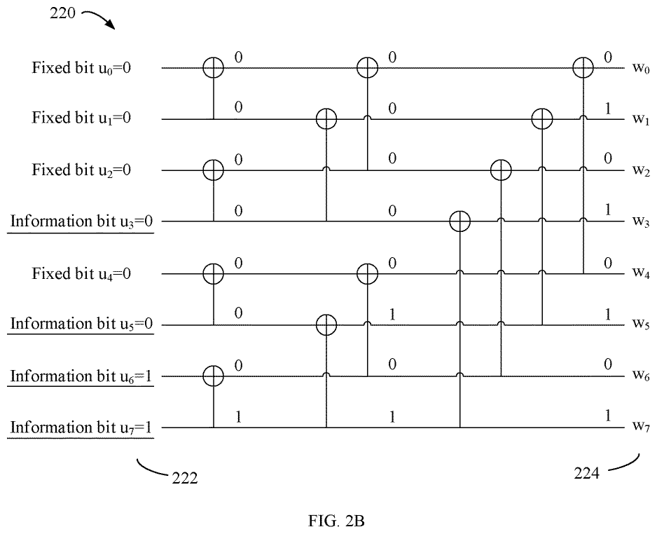

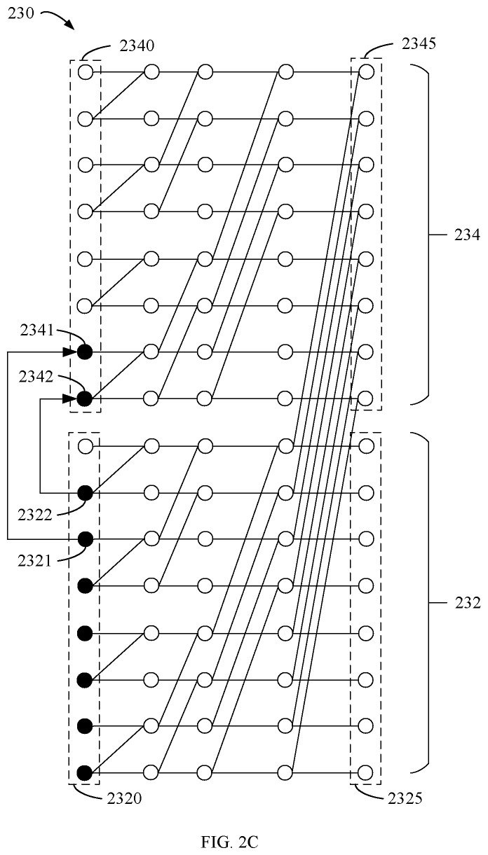

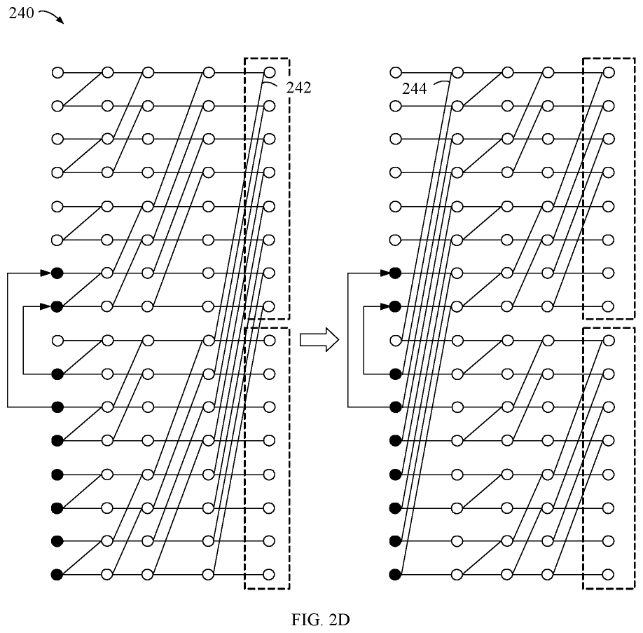

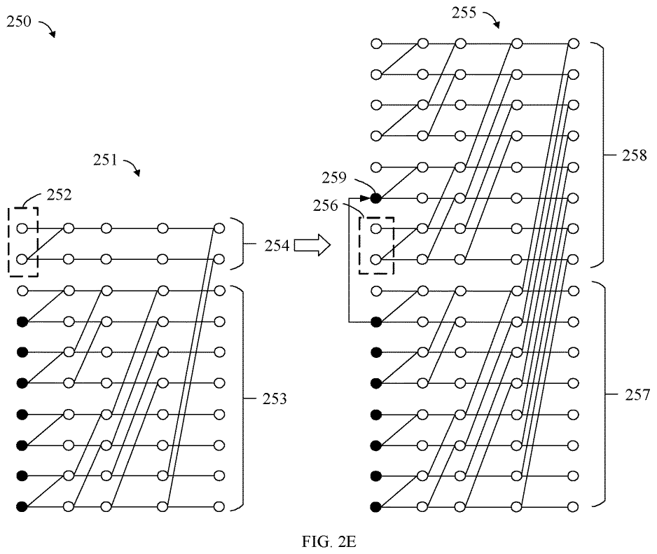

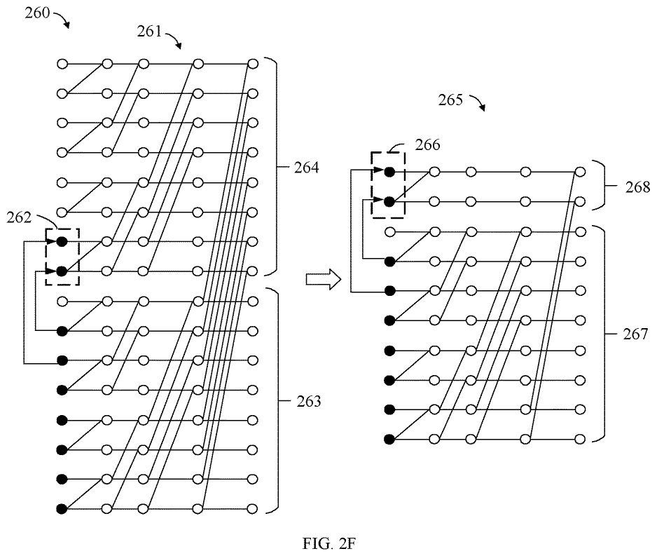

FIG. 2A is a diagram of processing 210 between a transmit end and a receive end in a communication system. As shown in FIG. 2A, at the transmit end, data of a source 211 is processed through source encoding 212, channel encoding 213, and modulation 214 to obtain a modulated signal that enters a channel. At the receive end, the signal received from the channel is processed through demodulation 215, channel decoding 216, and source restoration 217 to obtain data of a sink 218. In addition, the receive end restores the data of the source 211 from the data of the sink 218 as much as possible.

For example, the transmit end in FIG. 2A may be the network device 110-1 in FIG. 1, and the receive end may be the network device 110-2 or the terminal device 120-1 in FIG. 1. Alternatively, for example, the transmit end in FIG. 2A may be the terminal device 120-1 in FIG. 1, and the receive end may be the network device 110-1 or the terminal device 120-2 in FIG. 1. It may be understood that the transmit end and the receive end in FIG. 2A may alternatively be implemented as another type of communication device. This is not limited in this disclosure.

FIG. 2B is a diagram of an 8×8 polar code 220 with 8 input bits and 8 output bits. In FIG. 2B, ⊕ indicates a bit exclusive OR operation. As shown in FIG. 2B, the eight bits to be encoded on the left may be classified into two types of bits, namely, fixed bits and information bits, based on a reliability ranking of a corresponding subchannel. The fixed bit may also be referred to as a frozen bit, and the information bit may also be referred to as a data bit. A subchannel with low reliability corresponds to a fixed bit. In actual transmission, the fixed bit may be known to both an encoder side and a decoder side. For example, the fixed bit may be set to “0”. A subchannel with high reliability corresponds to an information bit, and is used to carry information to be transmitted. As shown in FIG. 2B, in an input bit sequence 222, u₇, u₆, u₅, and u₃ are four information bits at subchannels with high reliability, and u₄, u₂, u₁, and up are four fixed bits at subchannels with low reliability, for example, all are set to 0. After polar encoding is performed, an encoded bit sequence 224, for example, w₀ to w₇ shown in FIG. 2B, may be obtained.

A decoding method corresponding to polar encoding may be classified into two types based on a decoding time sequence: sequential decoding and non-sequential decoding. Sequential decoding means that the decoder side may perform decoding based on a natural time sequence of polar encoding. Non-sequential decoding means that the decoder side outputs a decoding result in parallel based on another structure of polar encoding, where the other structure may be, for example, a Tanner graph or a Trellis graph. Algorithms that can be used for sequential decoding include a successive cancellation (SC) decoding algorithm, a successive cancellation list (SCL) decoding algorithm, a successive cancellation stack (SCS) decoding algorithm, a cyclic redundancy check (CRC) aided successive cancellation list (CA-SCL) decoding algorithm, and the like. Algorithms that can be used for non-sequential decoding include a belief propagation (BP) decoding algorithm, and the like. In these decoding algorithms, the SCL decoding algorithm greatly improves decoding performance in comparison with the SC decoding algorithm. In addition, CRC is considered in the CA-SCL decoding algorithm, and therefore, the CA-SCL decoding algorithm has good decoding performance. Therefore, currently, mainly used decoding algorithms are the SCL decoding algorithm and the CA-SCL decoding algorithm.

Polar codes may be used for hybrid automatic repeat request (HARQ) transmission and support self-decoding, where HARQ is, for example, an IR-HARQ.

In the HARQ transmission, a forward error correction (FEC) method and an automatic repeat request (ARQ) method are jointly used, so that spectral efficiency can be significantly improved. The transmit end sends a symbol sequence corresponding to an encoded packet as initial transmission. The receive end receives the symbol sequence and attempts to perform decoding. If decoding succeeds, the receive end feeds back an acknowledgement (ACK). The transmit end stops sending based on feedback information (namely, the ACK). If decoding fails, the receive end buffers the received symbol sequence or corresponding demodulation soft information, and feeds back a negative acknowledgement (NACK) or does not give feedback. If the transmit end receives the NACK (or does not receive the ACK), the transmit end continues to send an encoded bit sequence as incremental redundancy (IR). Then, the receive end may perform joint decoding based on two received symbol sequences. In comparison with a case in which data that is sent in a plurality of times in the HARQ transmission is sent at a time, an HARQ allows to stop sending data when the receive end successfully performs decoding during transmission. Therefore, a system throughput can be improved. If the initial transmission succeeds, the transmit end does not need to perform retransmission, thereby saving spectrum resources and improving spectral efficiency. If the initial transmission fails, the receive end performs joint decoding on the two received symbol sequences, so that error correction performance of a long code can still be achieved.

FIG. 2C is a diagram of a polar code 230 for IR-HARQ. In FIG. 2C, an initial transmission polar code 232 (represented by U code) with a length of 8 and a retransmission polar code 234 (represented by V code) with a length of 8 are included. An initial data transmission input bit sequence 2320, upon initial transmission polar encoding, generates an initial transmission encoded bit sequence 2325. A data retransmission input bit sequence 2340, upon retransmission polar encoding, generates a retransmission encoded bit sequence 2345. In addition, during retransmission polar encoding, information from the initial transmission polar code 232 is fully incorporated into the retransmission polar code 234.

For example, within the initial data transmission input bit sequence 2320 and the data retransmission input bit sequence 2340, solid dots indicate information bits, and hollow dots indicate fixed bits. In addition, an information bit 2341 in the data retransmission input bit sequence 2340 is replicated from, and thus identical to, an information bit 2321 in the initial data transmission input bit sequence 2320. An information bit 2342 in the data retransmission input bit sequence 2340 is replicated from, and thus identical to, an information bit 2322 in the initial data transmission input bit sequence 2320.

During decoding, if the initial transmission polar code 232 is separately decoded, 2321, 2322, 2341, and 2342 are all treated as information bits. However, in joint decoding, the initial transmission polar code 232 and the retransmission polar code 234 may be combined into a single polar code of length 16, where 2341 and 2342 are treated as information bits. During the decoding of bits 2321 and 2322, their values are predetermined by their identical counterparts at 2341 and 2342, thereby making 2321 and 2322 known values.

In this framework, regardless of whether the initial transmission polar code 232 is separately decoded or the initial transmission polar code 232 and the retransmission polar code 234 are jointly decoded, information bits are always carried at subchannels with high reliability, thereby ensuring optimal decoding performance. From a perspective of code rate allocation, establishing a one-to-one mapping relationship between part of information bits in the U code and part of information bits in the V code effectively relocates part of information bits from the initial transmission polar code 232 to the retransmission polar code 234, thereby implementing optimal allocation of code rates for the initial transmission polar code 232 and the retransmission polar code 234.

The direct transmission of a plurality of redundancy versions (RVs) is a common coverage enhancement method in wireless communication. Each RV may be understood as a code and supports independent decoding. The plurality of RVs may be combined to form a longer code to enhance decoding. In comparison with transmitting a single long code, multi-RV transmission allows the receive end to retain the capability to decode using a remaining RV when a single RV is completely lost. FIG. 2D is a diagram of a polar code 240 supporting self-decoding. As shown in FIG. 2D, the left side illustrates a fence diagram for a polar code. A fence diagram on the right side may be obtained by converting inter-stage interleaving between an initial transmission polar code and a retransmission polar code from 242 to 244. It can be learned that, when there is a one-to-one mapping relationship between the initial transmission polar code and the retransmission polar code (as shown in FIG. 2C), both the initial transmission polar code and the retransmission polar code individually encapsulate the complete information of the information bits. This enables a decoder at a receive end to rely solely on either the initial transmission polar code or the retransmission polar code for decoding under favorable channel conditions.

It can be learned that, before polar encoding is performed, information bits need to be placed in corresponding information positions. When a polar code for HARQ transmission or supporting self-decoding is constructed, a part of information bits need to be simultaneously mapped to a plurality of information positions. In other words, regardless of whether an IR-HARQ is used or self-decoding is supported, a feature of a one-to-one mapping relationship between information bits of the retransmission polar code and a part of information bits of the initial transmission polar code needs to be used. From a perspective of bit mapping, when equivalent long code bit mapping is constructed, a part of information bits needs to be mapped to both the initial transmission polar code and the retransmission polar code.

In an actual wireless communication scenario, there is a problem that a radio resource scheduled for HARQ retransmission adapts to an encoder structure. When an HARQ transmission mechanism is implemented in wireless communication, a quantity of retransmission resources is determined through system scheduling, and may be small or large. Encoding preferably supports rateless transmission, that is, encoding can be completed in advance, and then a corresponding quantity of codeword bits are extracted from an encoded bit sequence based on a quantity of retransmission resources scheduled by a system, to perform sending. In other words, “rateless” means that a code rate is not determined in advance, but is determined after a given resource is provided. The rateless transmission requires that performance is always close to optimal performance regardless of a quantity of codeword bits to be sent. For a polar code, it is expected that information bits are always at high-reliability channels regardless of a quantity of codeword bits to be sent. However, as “codeword bits” increase, reliability of subchannels and an order of the reliability of the subchannels change, and a design of the polar code may not meet the foregoing expectation. For example, when a length M of the retransmission polar code is 8, a 7^{th} bit and an 8^{th} bit are set to information bits. However, when the length M of the retransmission polar code is 2, the two bits need to be set to frozen bits. In this case, transmission performance in a scenario in which a scheduling resource is not adapted is affected regardless of whether the polar code is constructed based on M=2 or M=8.

FIG. 2E shows a scenario 250 in which a code is constructed based on M=2, and a retransmission scheduled coding length determined based on an actual retransmission resource M=8. As shown in FIG. 2E, an encoding structure 251 with the retransmission length M=2 includes an initial transmission polar code 253 and a retransmission polar code 254. A retransmission length M in the retransmission polar code 254 is 2, and two fixed bits are shown in a dashed box 252 due to an insufficient capacity. However, in actual data transmission, a large quantity of retransmission resources is scheduled for the retransmission polar code, for example, an actual retransmission length M=8, for example, an encoding structure 255 with the actual retransmission length M=8. The encoding structure 255 with the actual retransmission length M=8 includes an initial transmission polar code 257 and a retransmission polar code 258. A retransmission length M in the retransmission polar code 258 is 8, and two fixed bits are also shown in a dashed box 256 based on the encoding structure 251 with M=2. However, as the length of the retransmission polar code 258 increases, reliability of two subchannels in the dashed box 256 increases. In this case, fixed bits are still set at the two subchannels, causing a waste of resources of high-reliability subchannels. In this case, a mapping relationship is constructed through another subchannel (for example, 259). Because reliability of the subchannel at 259 is low, performance may deteriorate.

FIG. 2F shows a scenario 260 in which a code is constructed based on M=8, and a retransmission scheduled coding length determined based on an actual retransmission resource M=2. As shown in FIG. 2F, an encoding structure 261 with the retransmission length M=8 includes an initial transmission polar code 263 and a retransmission polar code 264. A retransmission length M in the retransmission polar code 264 is 8, and information bits are shown in a dashed box 262 due to higher reliability. However, in actual data transmission, a small quantity of retransmission resources is scheduled for the retransmission polar code, for example, an actual retransmission length M=2, for example, an encoding structure 265 with the actual retransmission length M=2. The encoding structure 265 with the actual retransmission length M=2 includes an initial transmission polar code 267 and a retransmission polar code 268. A retransmission length M in the retransmission polar code 268 is 2, and two information bits are also shown in a dashed box 266 based on the encoding structure 261 with M=8. However, because the length of the retransmission polar code 268 decreases, reliability of two subchannels in the dashed box 256 decreases. In this case, information bits are still set at the two subchannels, or transmission is unreliable, and a defect of a system may be caused.

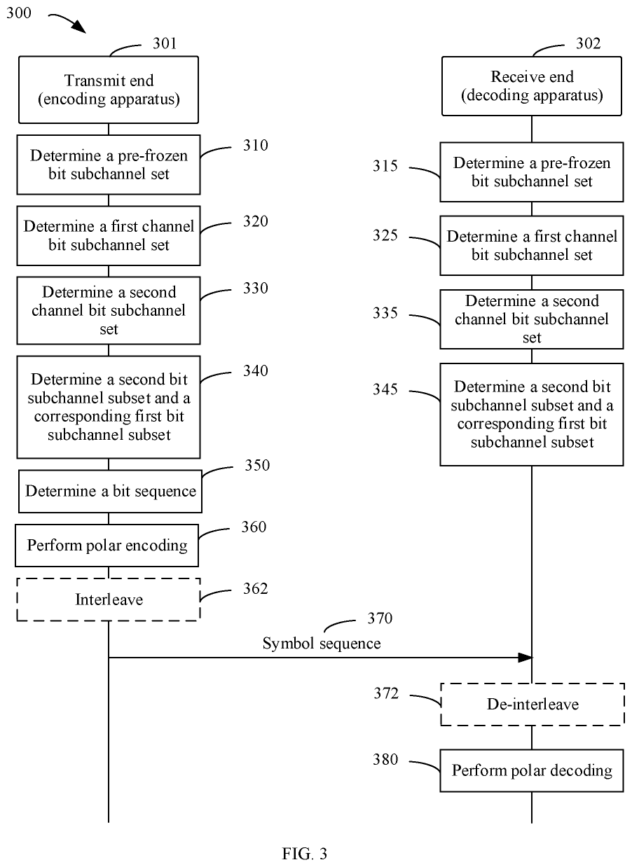

As can be seen from the examples in FIG. 2E and FIG. 2F, it is difficult to use a polar code to balance performance between small-scale retransmission and large-scale retransmission, resulting in poor flexibility. Therefore, an optimized solution is required to resolve at least the foregoing problem. The following describes main embodiments in this disclosure with reference to examples in FIG. 3 to FIG. 6.

FIG. 3 is a flowchart of an example process 300 according to some embodiments of this disclosure. The process 300 relates to a transmit end 301 and a receive end 302. For example, the transmit end 301 may include an encoding apparatus, and the receive end 302 may include a decoding apparatus. With reference to FIG. 1, the transmit end 301 may be implemented as the network device 110-1 in FIG. 1, and the receive end 302 may be implemented as the network device 110-2 or the terminal device 120-1 in FIG. 1. Alternatively, the transmit end 301 may be implemented as the terminal device 120-1 in FIG. 1, and the receive end 302 may be implemented as the network device 110-1 or the terminal device 120-2 in FIG. 1. It may be understood that the process 300 may alternatively be implemented in combination with another system. This is not limited in this disclosure.

For ease of description, in embodiments of this disclosure, it is assumed that a length of an information bit sequence to be encoded is K, and a total length of encoded bits is N₂, where both K and N₂ are positive integers, and K<N₂. For example, K indicates a sum of a quantity of information bits, a quantity of parity check (PC) bits, and a quantity of CRC bits. Optionally, N₂ may be equal to an integer power of 2. For example, N₂=32 or N₂=16, or another example is used. Optionally, a sequence whose total length of the encoded bits is N₂ may be sent in a plurality of segments (for example, two or more segments), or may be sent in a combined manner. For example, sending the sequence in the plurality of segments may correspond to a HARQ scenario, and sending the sequence in the combined manner may correspond to a scenario in which self-decoding is supported. In some examples, N₂=N×2. For ease of description, the following uses an example in which the total length of the encoded bits is 2N for description, where K<N, for example, N=8 or N is another value.

For ease of description, in embodiments of this disclosure, it is assumed that subchannel indices of 2N subchannels are 0 to 2N−1. However, it should be understood that, in an actual scenario, another numbering manner or rule may alternatively be used, for example, indices from 1 to 2N or from 2N−1 to 0 may be used. This is not limited in this disclosure. Different subchannels may have different reliability, and a reliability sequence of length 2N may be determined. For example, the reliability sequence of length 2N may indicate 2N subchannels in ascending order (or descending order) of reliability. The 2N subchannels include N subchannels numbered from 0 to N−1 and N subchannels numbered from N to 2N−1.

In some implementations, a reliability sequence of length N may be determined based on the reliability sequence of length 2N. In some embodiments, the reliability sequence of length N may be determined in any extraction manner. For example, the reliability sequence of length N may indicate a reliability order of N subchannels. For example, the N subchannels may be any N subchannels in the 2N subchannels. In some embodiments, a reliability sequence of length N and that corresponds to the N subchannels numbered from N to 2N−1 may be determined based on the reliability sequence of length 2N, for example, referred to as a first reliability subsequence and represented as seq1. For example, the first reliability subsequence (seq1) may be obtained based on the reliability sequence of length 2N in a nested reading or similar manner. For example, an element whose index is greater than or equal to N may be read from the reliability sequence, or an element whose index is less than N may be excluded from the reliability sequence, to form the first reliability subsequence. For example, a sequence constructed by elements whose indices are less than N in the reliability sequence of length 2N may be determined as the first reliability subsequence.

As shown in FIG. 3, in 310, the transmit end 301 determines a pre-frozen bit subchannel set. The pre-frozen bit subchannel set may be determined based on the reliability sequence of length 2N. For example, the pre-frozen bit subchannel set may be represented as F1, where the set F1 may include zero or several elements, and each element represents a corresponding subchannel. For example, an element of the pre-frozen bit subchannel set F1 is a subchannel index.

In some embodiments, a subchannel set with N1 elements may be determined from indices 0 to N−1, where N1 is a positive integer less than N. Optionally, N1 may be predefined. For example, N1=N/4, or N1=N/2, or N1 is another value. For example, a relationship between N1 and N may be preset, or a specific value of N1 (for example, N1=2) may be preset. Optionally, N1 may be determined based on a system-scheduled resource. For example, a value of N1 may be determined dynamically or online. For example, it may be determined that N1=2, or N1=4, or N1 is another value. It may be understood that the value of N1 may alternatively be determined or defined in another manner. For example, N1 may be defined as a value associated with K. This is not limited in this disclosure.

For example, N1 indices with largest indices may be selected from the indices 0 to N−1 to determine the subchannel set with N1 elements. For example, the subchannel set with N1 elements is represented as {N−N1, N−N1+1, . . . , N−1}.

For example, the subchannel indices 0 to N−1 may be ordered, N1 subchannel indices are selected (or extracted) from the ordered subchannel indices, and a set of the N1 subchannel indices is determined as a subchannel set with N1 elements. In some examples, 0 to N−1 may be ordered in descending order (or ascending order) in a natural order, and then N1 indices may be selected from left to right (or from right to left) from the ordered indices, that is, in descending order (or in ascending order), so that N1 subchannel indices with larger indices are extracted. In some other examples, a corresponding interleaved order may be obtained, and N1 indices may be selected in a reverse order, so that N1 subchannel indices are extracted. For example, the interleaved order corresponding to 0 to N−1 may be pre-stored. For example, the correspondence may be predetermined. In some other examples, an order after subsequent interleaving (for example, in 362) may be considered. For example, an order of the subchannel indices 0 to N−1 after subsequent interleaving may be determined. Then, N1 indices are selected from the interleaved order in a reverse order, so that N1 subchannel indices are extracted.

In some embodiments, a second reliability subsequence of length N+N1 may be determined based on the reliability sequence of length 2N, for example, may be represented as seq2. The second reliability subsequence may be determined based on the reliability sequence of length 2N and the foregoing subchannel set with N1 elements. For example, the second reliability subsequence (namely, seq2) that corresponds to the N subchannel indices corresponding to the first reliability subsequence (namely, seq1) and the N1 subchannel indices in the subchannel set may be extracted from the reliability sequence of length 2N. For example, the second reliability subsequence (seq2) may correspond to N+N1 subchannel indices, and these subchannel indices include N subchannel indices during initial transmission and N1 subchannel indices in the determined subchannel set.

In some embodiments, the pre-frozen bit subchannel set may be determined based on the second reliability subsequence (seq2). For example, the pre-frozen bit subchannel set may be determined based on the second reliability subsequence (namely, seq2) and a predetermined threshold (for example, represented as T, where T is a positive number). Optionally, T is a positive integer, or T may be a positive non-integer. This is not limited in this disclosure. For example, the following uses an example in which T is a positive integer for description.

For example, the threshold (namely, T) may be predefined. For example, T may be equal to N, or T may be a function of N, for example, T=N−1. For example, the threshold (namely, T) may be determined based on a ratio of K to (N+N1). For example, T may be a function of K/(N+N1). For example, K/(N+N1) may be compared with a predetermined threshold (for example, represented as R1). If K/(N+N1) is less than (or less than or equal to) the predetermined threshold, the threshold is equal to a first value. If K/(N+N1) is greater than or equal to (or greater than) the predetermined threshold, the threshold is equal to a second value. Optionally, the predetermined threshold may be any value within a range. For example, the range may be [130/512−δ1, 130/512+δ2], where δ1 and δ2 are positive values, and 81 and 82 may be equal or may not be equal. For example, δ1=δ2=130/512, or δ1 and δ2 are other values. This is not limited in this disclosure. Optionally, the first value may be equal to N or another value. Optionally, the second value may be equal to or not equal to the first value. For example, the second value is less than the first value. For example, the second value is equal to the first value minus a difference (for example, the difference is equal to 1 or another value). Optionally, the second value may be defined as a function of N, for example, an integer associated with 63/64×N. For example, the second value is equal to a nearest integer to which 63/64×N is rounded down, that is, └63/64×N┘ or floor(63/64×N). For example, the second value is equal to a nearest integer to which 63/64×N is rounded up, that is, └63/64×N┘ or ceil(63/64×N). For example, the second value is equal to an integer obtained by rounding 63/64×N, that is, round(63/64×N). For example, the second value is equal to 63/64×N.

Although it is assumed that there is one threshold in the foregoing example, in some other examples, a plurality of thresholds, for example, two or more thresholds (for example, T1 and T2), may be determined, and the pre-frozen bit subchannel set may be determined based on the plurality of thresholds.

For example, the pre-frozen bit subchannel set may be represented as F1, and the set F1 may be an empty set or a non-empty set. In other words, a quantity of elements in the pre-frozen bit subchannel set F1 may be 0 or may be non-zero (that is, greater than 0). In addition, the pre-frozen bit subchannel set F1 belongs to a subset of the foregoing subchannel set with N1 elements. In other words, the quantity of elements in the pre-frozen bit subchannel set F1 is not greater than (less than or equal to) N1.

For example, K subchannel indices with high reliability may be obtained based on the second reliability subsequence seq2, where all the obtained K subchannel indices are associated with the second reliability subsequence. For example, the K subchannel indices may be obtained in descending order of reliability. For example, the obtained K subchannel indices may be sequentially compared with the threshold to determine the pre-frozen bit subchannel set F1.

Optionally, the obtained K subchannel indices are separately compared with the threshold, and it is determined that a quantity of subchannel indices that are less than (or less than or equal to) the threshold is K1. Then, the K1 subchannel indices with high reliability in the subchannel set with N1 elements may be removed, and obtained (for example, remaining) N1−K1 subchannel indices may be determined as the pre-frozen bit subchannel set F1.

An index with highest reliability among the K subchannel indices (for ease of description, referred to as a first index) may be compared with the threshold. If the first index is greater than or equal to (or greater than) the threshold, a subchannel with highest reliability in the sequence numbers from N to 2N−1 is marked as a candidate information bit subchannel. Finally, an index with second highest reliability among the K subchannel indices (for ease of description, referred to as a second index) is compared with the threshold. If the second index is greater than or equal to (or greater than) the threshold, a subchannel with second highest reliability in the sequence numbers from N to 2N−1 is marked as a candidate information bit subchannel. On the contrary, if the second number is less than (or less than or equal to) the threshold, a subchannel with highest reliability in the subchannel set with N1 elements is marked as a candidate information bit subchannel. In this manner, the K subchannel indices with high reliability are sequentially compared with the threshold, and subchannels (whose index is greater than or equal to the threshold) in the sequence numbers from N to 2N−1 or subchannels (whose index is less than the threshold) in the subchannel set with N1 elements are also marked as candidate information bit subchannels in descending order of reliability. Optionally, after the comparison between the K subchannel indices and the threshold is completed, K candidate information bit subchannels may be determined. Optionally, K1 candidate information bit subchannels may be determined in the subchannel set with N1 elements. For example, K1 may be equal to 0, or may be equal to any value from 1 to N1. Further, a set of remaining subchannels (namely, subchannels that are not marked as candidate information bit subchannels) in the subchannel set with N1 elements is determined as the pre-frozen bit subchannel set F1. It may be understood that a quantity of elements in the pre-frozen bit subchannel set F1 is equal to N1−K1.

In this way, in this solution, the pre-frozen bit subchannel set can be determined based on the threshold. A code rate can be reduced in a targeted manner by configuring a proper threshold, thereby improving performance. In addition, it should be understood that, in embodiments of this disclosure, after the pre-frozen bit subchannel set is obtained in the foregoing manner, a quantity of subchannels in the pre-frozen bit subchannel set may be further adjusted, for example, the quantity may be slightly adjusted by using +1 or −1.

In the process 300, a first information bit subchannel set is determined in 320. The first information bit subchannel set may be determined based on the first reliability subsequence, for example, may be represented as H1. A quantity of elements in the first information bit subchannel set H1 is equal to K, and the K elements in the first information bit subchannel set H1 indicates K subchannels with high reliability in subchannels numbered from N to 2N−1. For example, the K subchannel indices with high reliability may be determined based on the first reliability subsequence to obtain the first information bit subchannel set H1.

It should be noted that although the operation 320 is shown in FIG. 3 as being performed after the operation 310, in an actual scenario, the operation 320 may be performed before the operation 310, or the operation 320 may be performed simultaneously or in parallel with the operation 310. This is not limited in this disclosure.

In the process 300, a second information bit subchannel set is determined in 330. The second information bit subchannel set may be determined based on the reliability sequence and the pre-frozen bit subchannel set, for example, may be represented as H2. A quantity of elements in the second information bit subchannel set H2 is equal to K. For example, K subchannel indices with high reliability that do not belong to the pre-frozen bit subchannel set may be determined based on the reliability sequence to obtain the second information bit subchannel set.

In some examples, subchannel indices with high reliability may be read (for example, sequentially read in descending order of reliability) from the reliability sequence. If a read subchannel index does not belong to the pre-frozen bit subchannel set F1, the read subchannel index is added to the second information bit subchannel set H2, and then a next subchannel index with high reliability is read, . . . , until the quantity of elements in the second information bit subchannel set H2 is K.

In some examples, subchannel indices in the pre-frozen bit subchannel set may be removed from the reliability sequence to obtain a third reliability subsequence, for example, represented as seq3. Then, the K subchannel indices with high reliability may be obtained based on the third reliability subsequence to obtain the second information bit subchannel set H2.

It should be noted that although the operation 330 is shown in FIG. 3 as being performed after the operation 320, in an actual scenario, the operation 330 may be performed after the operation 310 and before the operation 320, or the operation 330 may be performed after the operation 310 and simultaneously or in parallel with the operation 320. This is not limited in this disclosure.

In the process 300, a second bit subchannel subset and a corresponding first bit subchannel subset are determined in 340. The second bit subchannel subset may be obtained based on a subchannel index that is less than N in the second information bit subchannel set. Then, a same quantity of subchannel indices with low reliability in the first information bit subchannel set may be determined based on a quantity of elements in the second bit subchannel subset to obtain the first bit subchannel subset.

In some examples, subchannel indices whose indices are between 0 and N−1 may be extracted from the second information bit subchannel set H2 to obtain the second bit subchannel subset. It is assumed that the quantity of elements in the second bit subchannel subset is Q. In this case, Q subchannel indices with lower reliability may be extracted from the first information bit subchannel set H1 to obtain the first bit subchannel subset. It may be understood that Q is an integer greater than or equal to 0.

For example, the elements in the second bit subchannel subset are in a one-to-one correspondence with elements in the first bit subchannel subset. A specific form of the correspondence is not limited in embodiments of this disclosure. For example, a smallest index in the second bit subchannel subset corresponds to a largest index, a smallest index, or another index in the first bit subchannel subset.

In the process 300, a bit sequence is determined in 350. In a scenario like a HARQ scenario, an initial transmission bit sequence and a retransmission bit sequence may be included. In a scenario like a self-decoding supported scenario, a long bit sequence may be included.

For example, a bit sequence (for example, the initial transmission bit sequence) mapped to the subchannels N to 2N−1 may be determined or generated, where an information bit is carried at each subchannel that belongs to the first information bit subchannel set (including the first bit subchannel subset). For example, a bit sequence (for example, the retransmission bit sequence) mapped to the subchannels 0 to N−1 may be determined or generated, where an information bit is carried at each subchannel that belongs to the second bit subchannel subset, and is determined based on an information bit carried at a subchannel in the corresponding first bit subchannel subset. For example, it is assumed that a subchannel AA in the second bit subchannel subset corresponds to a subchannel BB in the first bit subchannel subset, and an information bit at the subchannel BB is 1 (or 0). In this case, an information bit at the subchannel AA may also be 1 (or 0). For example, the information bit at the subchannel AA may be a copy of the information bit at the corresponding subchannel BB.

In 360, polar encoding is performed on the bit sequence to obtain an encoded result. For example, polar encoding may be performed in a manner similar to that shown in FIG. 2C or FIG. 2D. The specific implementation is not limited in this disclosure.

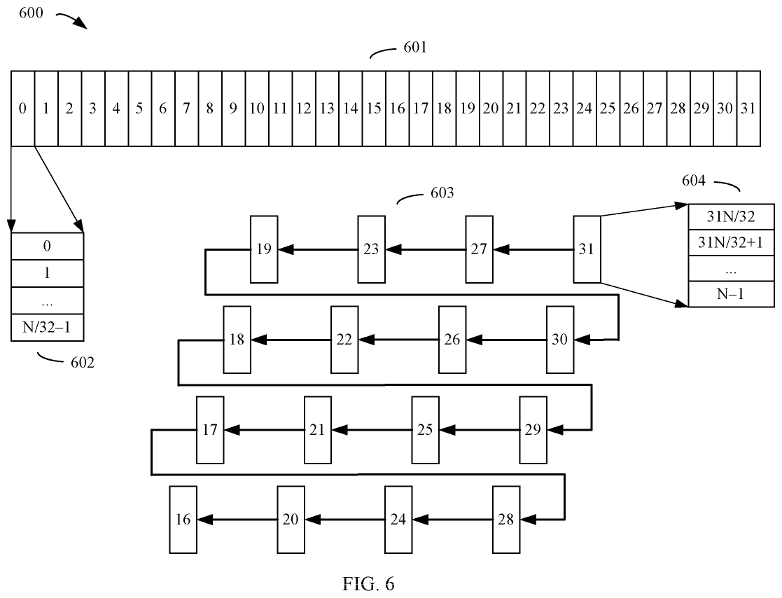

Additionally or alternatively, in 362, interleaving may be performed based on the encoded result to obtain an interleaved bit sequence. For example, interleaving in 362 may be implemented as bit interleaving, random interleaving, triangular interleaving, row-column interleaving, reverse interleaving, or the like, to implement a more refined or flexible interleaving manner. For an example of interleaving, refer to the following descriptions in FIG. 6.

In 370, a symbol sequence is sent. For example, one or more bits from the interleaved bit sequence may be sent as the symbol sequence based on the interleaved bit sequence. For example, a quantity of bits in the symbol sequence (represented as an integer P) may be determined based on the system-scheduled resource. For example, P bits may be extracted from the interleaved bit sequence in a reverse order as the symbol sequence to be sent.

In the process 300 shown in FIG. 3, from a perspective of the receive end 302, the pre-frozen bit subchannel set may be determined in 315, the first information bit subchannel set may be determined in 325, the second information bit subchannel set may be determined in 335, and the second bit subchannel subset and the corresponding first bit subchannel subset may be determined in 345. For specific implementations of 315, 325, 335, and 345, refer to the implementations of 310, 320, 330, and 340 described above with reference to the transmit end 301. For brevity, details are not repeated here.

It should be noted that operations performed at the transmit end 301 and operations performed at the receive end 302 are independent of each other. For example, from a timing perspective, the operation 315 may be performed before or after the operation 310, such as after the operation 362; the operation 345 may be performed before or after the operation 310, such as in parallel with the operation 340. This is not limited in this disclosure.

In 370, the receive end 302 receives the symbol sequence from the transmit end 301. Optionally, padding may be performed on the received symbol sequence to obtain a padded symbol sequence. For example, the padding position and manner may be determined based on the system-scheduled resource.

Additionally or alternatively, in 372, the receive end 302 performs de-interleaving on the padded symbol sequence to obtain a de-interleaved symbol sequence. For example, the de-interleaving operation is the inverse of the interleaving operation previously performed at the transmit end 301.

In 380, the receive end 302 performs polar decoding on the de-interleaved symbol sequence to obtain a bit sequence. For example, the decoding operation is the inverse of the encoding operation previously performed at the transmit end 301.

In this way, in embodiments of this disclosure, the bit sequence may be determined based on a subchannel set with N1 elements (N1 subchannel sequence numbers), instead of based on N subchannel sequence numbers from 0 to N−1. In this way, fine-grained and flexible encoding for transmission can be implemented. In addition, according to embodiments of this disclosure, the implementation complexity is low, thereby ensuring performance stability.

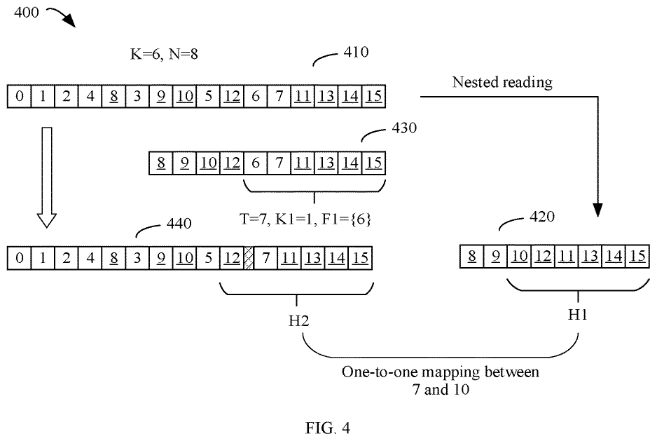

FIG. 4 is a diagram of an example 400 of determining a second bit subchannel subset and a first bit subchannel subset according to some embodiments of this disclosure. In the example of FIG. 4, it is assumed that N=8, K=6, and a reliability sequence 410 with a length of 2N is [0, 1, 2, 4, 8, 3, 9, 10, 5, 12, 6, 7, 11, 13, 14, 15].

In the example 400 of FIG. 4, a subchannel set with N1=2 elements determined from subchannel indices 0 to N−1 is {6, 7}. For example, N1=2 subchannel indices with largest indices may be extracted from the subchannel indices 0 to N−1. Through nested reading, a first reliability subsequence 420, namely, [8, 9, 10, 12, 11, 13, 14, 15], corresponding to subchannel indices N to 2N−1 may be determined based on the reliability sequence 410. In addition, a first information bit subchannel set H1={10, 12, 11, 13, 14, 15} may be determined in descending order of reliability.

Based on the reliability sequence 410 and the subchannel set {6, 7} with N1=2 elements, a second reliability subsequence 430, namely, [8, 9, 10, 12, 6, 7, 11, 13, 14, 15], may be determined.

Optionally, because K/(N+N1)=6/10 is greater than 130/512, a threshold may be set to T=7. Based on K=6 subchannel indices with high reliability in the second reliability subsequence 430, namely, 6, 7, 11, 13, 14, and 15, and by comparing each subchannel index with the threshold, it may be determined that a quantity of candidate information bits in the subchannel set {6, 7} is K1=1, and therefore a pre-frozen bit subchannel set may be further determined as F1={6}.

In the example 400, a third reliability subsequence 440 may be determined based on the reliability sequence 410 and the pre-frozen bit subchannel set F1={6}, and a second information bit subchannel set H2={12, 7, 11, 13, 14, 15} may be determined in descending order of reliability.

Because {7} in the second information bit subchannel set H2 belongs to the subchannel set {6, 7} with N1=2 elements, and a subchannel with lowest reliability in the first information bit subchannel set H1 is 10, a one-to-one mapping relationship may be established between subchannel indices 7 and 10.

It may be understood that the example 400 in FIG. 4 is merely an example rather than a limitation. In an actual scenario, for example, K subchannel indices with high reliability in the second reliability subsequence may not include any subchannel index in a subchannel set with N1 elements. For example, the second information bit subchannel set H2 may include zero, one, or more subchannel indices that belong to the subchannel set with N1 elements. This is not limited in this disclosure.

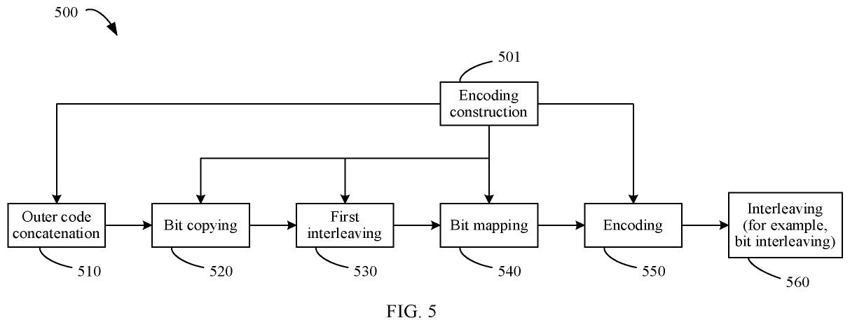

FIG. 5 is a diagram of an example process 500 of a transmit end (an encoding apparatus) according to an embodiment of this disclosure. The example process 500 may include some or all steps or operations illustrated in the figure: encoding construction 501, outer code concatenation 510, bit copying 520, first interleaving 530, bit mapping 540, encoding 550, and interleaving 560.

For example, the encoding construction 501 may correspond to operations 310 to 350 discussed in FIG. 3, encoding 550 may correspond to the operation 360 discussed in FIG. 3, and interleaving 560 may correspond to the operation 362 discussed in FIG. 3. In this way, a more flexible encoding manner can be implemented by combining the encoding construction 501 with interleaving 560, and better support for rate-free transmission can be provided.

For example, the interleaving operation 362 in the process 300 in FIG. 3 may correspond to interleaving 560 shown in FIG. 5. For example, interleaving 560 may be implemented in a sub-block interleaving manner, to simplify implementation of interleaving and obtain good performance.

In some embodiments, an encoded result obtained through encoding 550 may be divided into 32 sub-blocks, and sequence numbers of the sub-blocks may be 0 to 31 (or may be 1 to 32 in another example). FIG. 6 is a diagram of sub-block interleaving 600 according to some embodiments of this disclosure. As shown in FIG. 6, the encoded result is divided into 32 sub-blocks 601 whose sequence numbers are 0 to 31, and an order of interleaved sub-blocks is [0, 4, 8, 12, 1, 5, 11, 13, 2, 6, 10, 14, 3, 7, 11, 15, 16, 20, 24, 28, 17, 21, 25, 29, 18, 22, 26, 30, 19, 23, 27, 31]. As an example, if the encoded result includes an N-bit bit sequence corresponding to the subchannel indices 0 to N−1, bits 602 in the sub-block 0 are 0, 1, . . . , and N/32−1. In an output sequence 603 obtained through sub-block interleaving, an output order of the sub-blocks is: 31, 27, 23, 19, 30, 26, 22, 18, 29, 25, 21, 17, 28, 24, 20, 16, . . . , and the like, where bits 604 in the sub-block 31 are: 31N/32, 31N/32+1, . . . , and N−1.

In this manner, in the sub-block interleaving manner shown in FIG. 6, performance of small-scale retransmission and performance of large-scale retransmission can be balanced, and flexibility of a polar code IR-HARQ can be improved.

According to the example embodiments of this disclosure described above, a bit sequence to be encoded may be determined based on a subchannel set with N1 elements (with N1 subchannel sequence numbers). In this way, fine-grained and flexible encoding for transmission can be implemented. In addition, according to embodiments of this disclosure, the implementation complexity is low, thereby ensuring performance stability.

It should be noted that although the foregoing embodiments are described by using polar coding as an example, in some other scenarios, the solution may be changed, updated, replaced, or the like for use in another type of encoding and decoding process. This is not limited in this disclosure.

It should be further understood that division into the manners, cases, categories, and embodiments in embodiments of this disclosure is only intended for ease of description, and should not constitute a particular limitation. The features in the manners, categories, cases, and embodiments may be combined with each other if logical.

It should be further understood that, the foregoing content is only intended to help a person skilled in the art better understand embodiments of this disclosure, instead of limiting the scope of embodiments of this disclosure. A person skilled in the art may make various modifications, variations, combinations, or the like based on the foregoing content. A modified, changed, or combined solution also falls within the scope of embodiments of this disclosure.

It should be further understood that the foregoing content descriptions focus on differences between embodiments. For same or similar parts, refer to each other. For brevity, details are not described herein again.

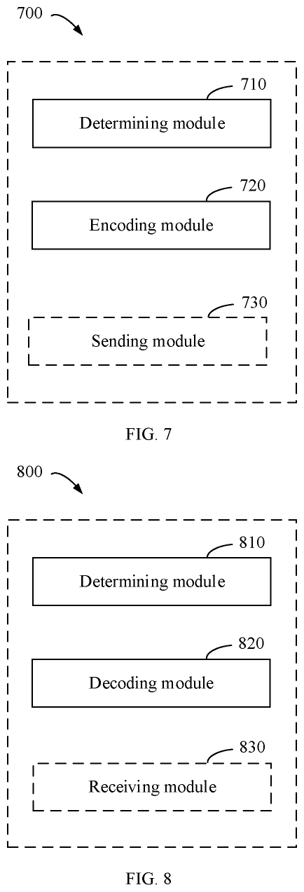

FIG. 7 is a block diagram of an example communication apparatus 700 according to some embodiments of this disclosure. The communication apparatus 700 may be implemented as an encoding apparatus, an encoder, a transmit end device, a part (for example, a chip) of a transmit end device, or the like. This is not limited in this disclosure. With reference to FIG. 3, the communication apparatus 700 may be implemented as the transmit end 301 shown in FIG. 3, a part (for example, a chip) of the transmit end 301, or the like. This is not limited in this disclosure. As shown in FIG. 7, the communication apparatus 700 includes a determining module 710 and an encoding module 720, and optionally includes a sending module 730.

The determining module 710 is configured to determine a pre-frozen bit subchannel set based on a reliability sequence of length N₂, where a quantity of elements in the pre-frozen bit subchannel set is greater than or equal to 0, and N₂ is a positive integer. The determining module 710 is further configured to determine a first information bit subchannel set based on a first reliability subsequence of length N in the reliability sequence, where N is a positive integer and N is less than N₂. The determining module 710 is further configured to determine a second information bit subchannel set based on the reliability sequence and the pre-frozen bit subchannel set. The determining module 710 is further configured to determine, based on a second bit subchannel subset in the second information bit subchannel set, a corresponding first bit subchannel subset in the first information bit subchannel set. The determining module 710 is further configured to determine a bit sequence based on the first bit subchannel subset and the second bit subchannel subset. The encoding module 720 is configured to perform polar encoding on the bit sequence to obtain an encoded result.

In some examples, the determining module 710 is configured to: determine, from subchannel indices 0 to N−1, a subchannel set with N₁ elements, where N₁ is a positive integer less than N; determine, based on the reliability sequence and the subchannel set, a second reliability subsequence of length N+N1; and determine the pre-frozen bit subchannel set based on the second reliability subsequence. Optionally, a value of N₁ is predetermined, or is determined based on a system-scheduled resource.

For example, the determining module 710 is configured to: obtain K subchannel indices with high reliability based on the second reliability subsequence, where K indicates a quantity of bits to be encoded, and K is a positive integer less than or equal to N; and determine the pre-frozen bit subchannel set from the subchannel set based on the K subchannel indices and the predetermined threshold.

For example, the determining module 710 is configured to: if a first subchannel index among the K subchannel indices is less than or does not exceed the threshold, mark an unmarked subchannel with highest reliability in the subchannel set as a candidate information bit; and after completing comparison for each of the K subchannel indices, determine a set of unmarked subchannels in the subchannel set as the pre-frozen bit subchannel set.

For example, the determining module 710 is configured to obtain N₁ subchannel indices in descending order from the subchannel indices 0 to N−1 arranged in a natural order to determine the subchannel set with N₁ elements. For example, the determining module 710 is configured to obtain N₁ subchannel indices in a reverse order based on an interleaved order corresponding to the subchannel indices 0 to N−1 to determine the subchannel set with N₁ elements.

For example, the determining module 710 is configured to determine the threshold based on K, N, and N₁, where K indicates the quantity of bits to be encoded, and K is a positive integer less than or equal to N. Optionally, the determining module 710 is configured to: in response to K/(N+N₁) being less than or equal to 130/512, determine that the threshold is equal to N; or in response to K/(N+N₁) being greater than 130/512, determine that the threshold is equal to └63/64×N┘. Optionally, when K/(N+N₁) is equal to the boundary value 130/512, another branch may alternatively be selected, that is, it is determined that the threshold is equal to └63/64×N┘. Similarly, in other embodiments of this disclosure, processing in which a value is a boundary value may also be performed in this way.

For example, the determining module 710 is configured to extract, from the reliability sequence, the second reliability subsequence of length N+N₁, where N+N₁ subchannel indices corresponding to the second reliability subsequence include N subchannel indices corresponding to the first reliability subsequence and the N₁ subchannel indices in the subchannel set.

In some examples, the determining module 710 is configured to determine, based on the first reliability subsequence, the K subchannel indices with high reliability to obtain the first information bit subchannel set.

In some examples, the determining module 710 is configured to determine, based on the reliability sequence, K subchannel indices with high reliability that do not belong to the pre-frozen bit subchannel set to obtain the second information bit subchannel set.

In some examples, the determining module 710 is configured to: obtain the second bit subchannel subset based on a subchannel index that is less than N in the second information bit subchannel set; and determine, based on a quantity of elements in the second bit subchannel subset, a same quantity of subchannel indices with low reliability in the first information bit subchannel set to obtain the first bit subchannel subset.

Optionally, one or more subchannel indices in the second bit subchannel subset are in a one-to-one correspondence with one or more subchannel indices in the first bit subchannel subset.

Optionally, the bit sequence includes an information bit at each subchannel in the second bit subchannel subset, and the information bit at each subchannel in the second bit subchannel subset is the same as an information bit at each subchannel in the corresponding first bit subchannel subset.

In some examples, the communication apparatus 700 may further include an interleaving module, configured to perform interleaving based on the encoded result to obtain an interleaved bit sequence. For example, the sending module 730 may be configured to output one or more bits from the interleaved bit sequence.

The communication apparatus 700 can be configured to implement the foregoing processes performed by the transmit end 301 in FIG. 3. For brevity, details are not described herein again.

FIG. 8 is a block diagram of an example communication apparatus 800 according to some embodiments of this disclosure. The communication apparatus 800 may be implemented as a decoding apparatus, a decoder, a receive end device, a part (for example, a chip) of a receive end device, or the like. This is not limited in this disclosure. With reference to FIG. 3, the communication apparatus 800 may be implemented as the receive end 302 shown in FIG. 3, a part (for example, a chip) of the receive end 302, or the like. This is not limited in this disclosure. As shown in FIG. 8, the communication apparatus 800 includes a determining module 810 and a decoding module 820, and optionally includes a receiving module 830.

The receiving module 830 may be configured to receive a symbol sequence. The determining module 810 is configured to determine a pre-frozen bit subchannel set based on a reliability sequence of length N₂, where a quantity of elements in the pre-frozen bit subchannel set is greater than or equal to 0, and N₂ is a positive integer. The determining module 810 is further configured to determine a first information bit subchannel set based on a first reliability subsequence of length N in the reliability sequence, where N is a positive integer and N is less than N₂. The determining module 810 is further configured to determine a second information bit subchannel set based on the reliability sequence and the pre-frozen bit subchannel set. The determining module 810 is further configured to determine, based on a second bit subchannel subset in the second information bit subchannel set, a corresponding first bit subchannel subset in the first information bit subchannel set. The decoding module 820 is configured to decode the symbol sequence based on the first bit subchannel subset and the second bit subchannel subset to obtain a bit sequence.

In some examples, the communication apparatus 800 further includes a padding module and a de-interleaving module. The padding module is configured to pad the symbol sequence to obtain a padded symbol sequence. The de-interleaving module is configured to perform de-interleaving based on the padded symbol sequence to obtain a de-interleaved symbol sequence. In addition, the decoding module 820 is configured to perform polar decoding on the de-interleaved symbol sequence to obtain the bit sequence.

In some examples, the determining module 810 is configured to: determine, from subchannel indices 0 to N−1, a subchannel set with N₁ elements, where N₁ is a positive integer less than N; determine, based on the reliability sequence and the subchannel set, a second reliability subsequence of length N+N₁; and determine the pre-frozen bit subchannel set based on the second reliability subsequence. For example, a value of N₁ is predetermined, or is determined based on a system-scheduled resource.

For example, the determining module 810 is configured to: obtain K subchannel indices with high reliability based on the second reliability subsequence, where K indicates a quantity of bits to be encoded, and K is a positive integer less than or equal to N; and determine the pre-frozen bit subchannel set from the subchannel set based on the K subchannel indices and the predetermined threshold.

For example, the determining module 810 is configured to: if a first subchannel index among the K subchannel indices is less than or does not exceed the threshold, mark an unmarked subchannel with highest reliability in the subchannel set as a candidate information bit; and after completing comparison for each of the K subchannel indices, determine a set of unmarked subchannels in the subchannel set as the pre-frozen bit subchannel set.

Optionally, the determining module 810 is configured to: obtain N₁ subchannel indices in descending order from the subchannel indices 0 to N−1 arranged in a natural order to determine the subchannel set with N₁ elements. Optionally, the determining module 810 is configured to: obtain N₁ subchannel indices in a reverse order based on an interleaved order corresponding to the subchannel indices 0 to N−1 to determine the subchannel set with N₁ elements.

For example, the determining module 810 is configured to determine the threshold based on a ratio of K to (N+N₁), where K indicates the quantity of bits to be encoded, and K is a positive integer less than or equal to N. Optionally, the determining module 810 is configured to: in response to K/(N+N₁) being less than or equal to 130/512, determine that the threshold is equal to N; or in response to K/(N+N₁) being greater than 130/512, determine that the threshold is equal to └63/64×N┘.

In some examples, the determining module 810 is configured to extract, from the reliability sequence, the second reliability subsequence of length N+N₁, where N+N₁ subchannel indices corresponding to the second reliability subsequence include N subchannel indices corresponding to the first reliability subsequence and the Ni subchannel indices in the subchannel set.

In some examples, the determining module 810 is configured to determine, based on the first reliability subsequence, the K subchannel indices with high reliability to obtain the first information bit subchannel set.

In some examples, the determining module 810 is configured to determine, based on the reliability sequence, K subchannel indices with high reliability that do not belong to the pre-frozen bit subchannel set to obtain the second information bit subchannel set.

In some examples, the determining module 810 is configured to: obtain the second bit subchannel subset based on a subchannel index that is less than N in the second information bit subchannel set; and determine, based on a quantity of elements in the second bit subchannel subset, a same quantity of subchannel indices with low reliability in the first information bit subchannel set to obtain the first bit subchannel subset.

For example, one or more subchannel indices in the second bit subchannel subset are in a one-to-one correspondence with one or more subchannel indices in the first bit subchannel subset.

For example, the bit sequence includes an information bit at each subchannel in the second bit subchannel subset, and the information bit at each subchannel in the second bit subchannel subset is the same as an information bit at each subchannel in the corresponding first bit subchannel subset.

In some examples, the receiving module 830 may be configured to receive an initial transmission symbol sequence. For example, the determining module 810 may be configured to determine, based on the initial transmission symbol sequence, the information bit at each subchannel in the first bit subchannel subset.

The communication apparatus 800 can be configured to implement the foregoing processes performed by the receive end 302 in FIG. 3. For brevity, details are not described herein again.

Division into the modules (or referred to as units, parts, or the like) in embodiments of this disclosure is an example, is merely logical function division, and may be other division during actual implementation. In addition, functional units in the disclosed embodiments may be integrated into one unit, each of the units may exist alone physically, or two or more units may be integrated into one unit. The integrated unit may be implemented in a form of hardware, or may be implemented in a form of a software functional unit.

An embodiment of this disclosure provides a communication device. The communication device may have the functions of the transmit end 301 and the functions of the receive end 302 described above. In some examples, the communication device may include the communication apparatus 700 and the communication apparatus 800. For example, the communication apparatus 700 and the communication apparatus 800 may be integrated on a chip in the communication device. For example, the communication device may be implemented as a terminal device, a network device, or the like.

An embodiment of this disclosure further provides a communication system, including a first device and a second device. The first device may include the communication apparatus 700, the second device may include the communication apparatus 800, and there is a wired or wireless communication interface between the first device and the second device. In some examples, the first device is a network device, and the second device is a terminal device. In some other examples, the first device is a terminal device, and the second device is a network device.

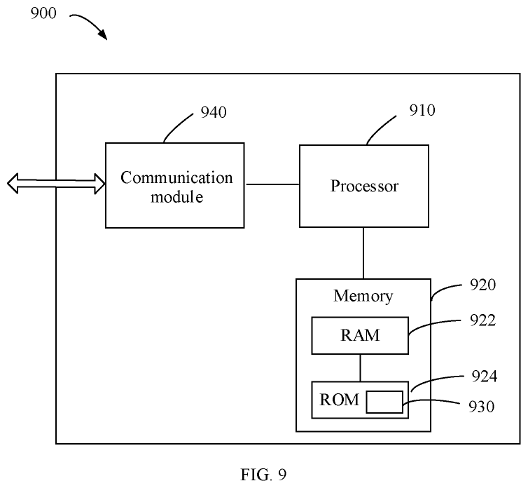

FIG. 9 is a block diagram of an example device 900 that may be used to implement an embodiment of this disclosure. The device 900 may be implemented as or included in the foregoing network device 110, terminal device 120, transmit end 301, or receive end 302. For example, the device 900 may be implemented as the transmit end 301 or the receive end 302 in FIG. 3.

As shown in FIG. 9, the device 900 includes one or more processors 910, one or more memories 920 coupled to the processor 910, and a communication module 940 coupled to the processor 910. Optionally, the memory may be integrated with the processor.

The communication module 940 may be configured for bidirectional communication. The communication module 940 may have at least one communication interface for communication. The communication interface may include any interface necessary for communicating with another device.

The processor 910 may be of any type suitable for a local technology network, and may include but is not limited to at least one of the following: a general-purpose computer, a dedicated computer, a microcontroller, a digital signal processor (DSP), or a controller-based multi-core controller architecture. The device 900 may have a plurality of processors, such as an application-specific integrated circuit chip, which in turn belongs to a clock synchronized with a main processor.

The memory 920 may include one or more non-volatile memories and one or more volatile memories. An example of the non-volatile memory includes but is not limited to at least one of the following: a read-only memory (ROM) 924, an erasable programmable read-only memory (EPROM), a flash memory, a hard disk, a compact disc (CD), a digital versatile disc (DVD), or other magnetic storage and/or optical storage. An example of the volatile memory includes but is not limited to at least one of the following: a random-access memory (RAM) 922, or another volatile memory that does not persist for duration of a power failure.

A computer program 930 includes computer-executable instructions performed by the associated processor 910. The program 930 may be stored in the ROM 924. The processor 910 may perform any suitable actions and processing by loading the program 930 into the RAM 922.

Embodiments of this disclosure may be implemented by using the program 930, so that the device 900 may perform any process discussed with reference to FIG. 3 to FIG. 6. Embodiments of this disclosure may alternatively be implemented by hardware or a combination of software and hardware.

The program 930 may be tangibly included in a computer-readable medium, and the computer-readable medium may be included in the device 900 (for example, in the memory 920) or another storage device that is accessible by the device 900. The program 930 may be loaded from the computer-readable medium to the RAM 922 for execution. The computer-readable medium may include any type of tangible non-volatile memory, for example, a ROM, an EPROM, a flash memory, a hard disk, a CD, or a DVD.

In some embodiments, the communication module 940 in the device 900 may be implemented as a transmitter and a receiver (or a transceiver), and may be configured to send/receive, for example, a symbol sequence. In addition, the device 900 may further include one or more of a scheduler, a controller, and a radio frequency/antenna. Details are not described in this disclosure.

For example, the device 900 in FIG. 9 may be implemented as an electronic device, or may be implemented as a chip or a chip system in the electronic device. This is not limited in embodiments of this disclosure.

An embodiment of this disclosure further provides a processing circuit. The processing circuit may implement operations described in some embodiments of this disclosure.

An embodiment of this disclosure further provides a chip. The chip may include an input interface, an output interface, and a processing circuit. In embodiments of the present disclosure, an input interface and an output interface may complete signaling or data exchange, and a processing circuit may complete generation and processing of signaling or data information.

An embodiment of this disclosure further provides a chip system, including a processor, configured to support a compute device in implementing functions in any one of the foregoing embodiments. In a possible design, the chip system may further include a memory, configured to store necessary program instructions and data. When the processor runs the program instructions, a device in which the chip system is installed is enabled to implement the method in any one of the foregoing embodiments. For example, the chip system may include one or more chips, or may include a chip and another discrete device.

An embodiment of this disclosure further provides a processor, configured to be coupled to a memory. The memory stores instructions. When the processor runs the instructions, the processor is enabled to perform the method and the function in any one of the foregoing embodiments.

An embodiment of this disclosure further provides a computer program or a computer program product including instructions. When the computer program or the computer program product is run on an apparatus, the apparatus is enabled to perform the method and the function in any one of the foregoing embodiments.

An embodiment of this disclosure further provides a non-transitory computer-readable storage medium. The non-transitory computer-readable storage medium stores computer instructions. When a processor runs the instructions, the processor is enabled to perform the method and the function in any one of the foregoing embodiments.

Usually, various embodiments of this disclosure may be implemented by hardware or a dedicated circuit, software, logic, or any combination thereof. Some aspects may be implemented by hardware, and other aspects may be implemented by firmware or software, and may be executed by a controller, a microprocessor, or another compute device. Although various aspects of embodiments of this disclosure are shown and described as block diagrams, a flowchart, or some other figures, it should be understood that the blocks, apparatuses, systems, techniques, or methods described in this specification may be implemented as, for example, non-limiting examples, hardware, software, firmware, dedicated circuits or logic, general-purpose hardware, controllers, other compute devices, or a combination thereof.

This disclosure further provides at least one computer program product tangibly stored in a non-transitory computer-readable storage medium. The computer program product includes computer-executable instructions, such as instructions included in a program module, which are executed in a device on a real or virtual target processor to perform the process/method as described above with reference to the accompanying drawings. Usually, the program module includes a routine, a program, a library, an object, a class, a component, a data structure, or the like that executes a specific task or implements a specific abstract data type. In various embodiments, functions of the program modules may be combined or split between the program modules as required. Machine-executable instructions for the program module may be executed locally or in a distributed device. In the distributed device, the program module may be located in a local storage medium and a remote storage medium.

Computer program code for implementing the method disclosed in this disclosure may be written in one or more programming languages. The computer program code may be provided for a processor of a general-purpose computer, a special-purpose computer, or another programmable data processing apparatus, so that when the program code is executed by the computer or the other programmable data processing apparatus, functions/operations specified in the flowcharts and/or block diagrams are implemented. The program code may be executed entirely on a computer, executed partially on a computer, executed as a standalone software package, executed partially on a computer and partially on a remote computer, or executed entirely on a remote computer or a server.

In the context of this disclosure, the computer program code or related data may be carried in any appropriate carrier, so that the device, the apparatus, or the processor can perform various processing and operations described above. Examples of the carrier include a signal, a computer-readable medium, and the like. Examples of the signal may include an electrical signal, an optical signal, a radio signal, a voice signal, or other forms of propagated signals, such as a carrier wave and an infrared signal.

The computer-readable medium may be any tangible medium that includes or stores programs used for or related to an instruction execution system, apparatus, or device. The computer-readable medium may be a computer-readable signal medium or a computer-readable storage medium. The computer-readable medium may include but is not limited to an electronic, magnetic, optical, electromagnetic, infrared, or semiconductor system, apparatus or device, or any suitable combination thereof. More detailed examples of the computer-readable storage medium include an electrical connection with one or more wires, a portable computer disk, a hard disk, a RAM, a ROM, an EPROM or a flash memory, an optical storage device, a magnetic storage device, or any suitable combination thereof.

In addition, although the operations of the methods in this disclosure are described in a particular order in the accompanying drawings, this does not require or imply that these operations need to be performed in the particular order, or that all the operations shown need to be performed to achieve the desired results. Instead, execution orders of the steps depicted in the flowchart may change. Additionally or alternatively, some steps may be omitted, a plurality of steps may be combined into one step for execution, and/or one step may be broken down into a plurality of steps for execution. It should further be noted that, the features and functions of two or more apparatuses according to this disclosure may be specific in one apparatus. Instead, features and functions of one apparatus described above may be further specific in a plurality of apparatuses.

The foregoing has described various implementations of this disclosure. The foregoing descriptions are examples, are not exhaustive, and are not limited to the disclosed implementations. Many modifications and changes are clear to a person of ordinary skill in the art without departing from the scope of the described implementations. Selection of the terms used in this specification is intended to well explain principles of the implementations, actual applications, or improvements to technologies in the market, or to enable another person of ordinary skill in the art to understand the implementations disclosed in this specification.

1. A method, comprising:
determining, based on a reliability sequence of length N₂, a pre-frozen bit subchannel set, wherein a quantity of elements in the pre-frozen bit subchannel set is greater than or equal to 0, and wherein N₂ is a positive integer;
determining, based on a first reliability subsequence of length N in the reliability sequence, a first information bit subchannel set, wherein N is a positive integer, and wherein N is less than N₂;
determining, based on the reliability sequence and the pre-frozen bit subchannel set, a second information bit subchannel set;
determining, based on a second bit subchannel subset in the second information bit subchannel set, a first bit subchannel subset in the first information bit subchannel set;
determining, based on the first bit subchannel subset and the second bit subchannel subset, a bit sequence; and
performing polar encoding on the bit sequence to obtain an encoded result.

2. The method of claim 1, wherein determining the pre-frozen bit subchannel set comprises:
determining, from subchannel indices 0 to N−1, a subchannel set with N₁ elements, wherein N₁ is a positive integer less than or equal to N, and wherein N₂=2×N;
determining, based on the reliability sequence and the subchannel set, a second reliability subsequence of length N+N₁; and
determining, based on the second reliability subsequence, the pre-frozen bit subchannel set.

3. The method of according to claim 2, wherein determining, based on the second reliability subsequence, the pre-frozen bit subchannel set comprises:
obtaining, based on the second reliability subsequence, K subchannel indices with a high reliability, wherein K indicates a quantity of bits to be encoded, and wherein K is a positive integer less than or equal to N; and
determining, from the subchannel set and based on the K subchannel indices and a threshold, the pre-frozen bit subchannel set.

4. The method of according to claim 3, wherein determining, from the subchannel set and based on the K subchannel indices and a threshold, the pre-frozen bit subchannel set comprises:
marking, for each subchannel index among the K subchannel indices, an unmarked subchannel with a highest reliability in the subchannel set as a candidate information bit when the subchannel index is less than or equal to the threshold; and
determining, after completing comparison for each of the K subchannel indices, a set of unmarked subchannels in the subchannel set as the pre-frozen bit subchannel set.

5. The method of claim 2, wherein determining the subchannel set comprises:
obtaining first N₁ subchannel indices in descending order from the subchannel indices 0 to N−1 arranged in a natural order to determine the subchannel set; or
obtaining second N₁ subchannel indices in a reverse order based on an interleaved order corresponding to the subchannel indices 0 to N−1 to determine the subchannel set.

6. The method of claim 3, further comprising:
determining, in response to K/(N+N₁) being less than or equal to 130/512, that the threshold is equal to N; or determining, in response to K/(N+N₁) being greater than 130/512, that the threshold is equal to └63/64×N┘.

7. The method of claim 2, wherein determining the second reliability subsequence comprises extracting, from the reliability sequence, the second reliability subsequence, and wherein N+N₁ subchannel indices corresponding to the second reliability subsequence comprise N subchannel indices corresponding to the first reliability subsequence and the N₁ subchannel indices in the subchannel set.

8. The method of claim 1, wherein determining the first information bit subchannel set comprises determining, based on the first reliability subsequence, first K subchannel indices with high reliability to obtain the first information bit subchannel set, wherein K is a positive integer indicating a quantity of bits to be encoded, wherein determining the second information bit subchannel set comprises determining, based on the reliability sequence, second K subchannel indices with high reliability that do not belong to the pre-frozen bit subchannel set to obtain the second information bit subchannel set, and wherein determining the corresponding first bit subchannel subset comprises:
obtaining, from the second information bit subchannel set, subchannel indices that are less than N as the second bit subchannel subset; and
determining, based on a quantity of elements in the second bit subchannel subset, a same quantity of subchannel indices with low reliability in the first information bit subchannel set to obtain the first bit subchannel subset.

9. The method of claim 1, wherein one or more first subchannel indices in the second bit subchannel subset are in a one-to-one correspondence with one or more second subchannel indices in the first bit subchannel subset.

10. The method of claim 1, wherein the bit sequence comprises, at each subchannel in the second bit subchannel subset, an information bit that is the same as a corresponding information bit at a corresponding subchannel in the first bit subchannel subset.

11. A communication method, comprising:
receiving a symbol sequence;
determining, based on a reliability sequence of length N₂, a pre-frozen bit subchannel set, wherein a quantity of elements in the pre-frozen bit subchannel set is greater than or equal to 0, and wherein N₂ is a positive integer;
determining, based on a first reliability subsequence of length N in the reliability sequence, a first information bit subchannel set, wherein N is a positive integer, and wherein N is less than N₂;
determining, based on the reliability sequence and the pre-frozen bit subchannel set, a second information bit subchannel set;
determining, based on a second bit subchannel subset in the second information bit subchannel set, a first bit subchannel subset in the first information bit subchannel set; and
decoding, based on the first bit subchannel subset and the second bit subchannel subset, the symbol sequence to obtain a bit sequence.

12. The method of claim 11, wherein decoding the symbol sequence comprises:
padding the symbol sequence to obtain a padded symbol sequence;
performing, based on the padded symbol sequence, de-interleaving to obtain a de-interleaved symbol sequence; and
performing polar decoding on the de-interleaved symbol sequence to obtain the bit sequence.

13. The method of claim 11, wherein determining the pre-frozen bit subchannel set comprises:
determining, from subchannel indices 0 to N−1, a subchannel set with N₁ elements, wherein N₁ is a positive integer less than N, and wherein N₂=2×N;
determining, based on the reliability sequence and the subchannel set, a second reliability subsequence of length N+N₁; and
determining, based on the second reliability subsequence, the pre-frozen bit subchannel set.

14. The method of claim 13, wherein determining, based on the second reliability subsequence, the pre-frozen bit subchannel set comprises:
obtaining, based on the second reliability subsequence, K subchannel indices with high reliability, wherein K indicates a quantity of bits to be encoded, and wherein K is a positive integer less than or equal to N; and
determining, from the subchannel set and based on the K subchannel indices and a threshold, the pre-frozen bit subchannel set.

15. The method of claim 14, wherein determining, from the subchannel set and based on the K subchannel indices and a threshold, the pre-frozen bit subchannel set comprises:
marking, for each subchannel index among the K subchannel indices, an unmarked subchannel with a highest reliability in the subchannel set as a candidate information bit when the subchannel index is less than or equal to the threshold; and
determining, after completing comparison for each of the K subchannel indices, a set of unmarked subchannels in the subchannel set as the pre-frozen bit subchannel set.

16. The method of claim 13, wherein determining the subchannel set comprises:
obtaining first N₁ subchannel indices in descending order from the subchannel indices 0 to N−1 arranged in a natural order to determine the subchannel set; or
obtaining second N₁ subchannel indices in a reverse order based on an interleaved order corresponding to the subchannel indices 0 to N−1 to determine the subchannel set.

17. The method of claim 14, further comprising determining, based on K, N, and N₁, the threshold, and wherein determining the threshold comprises:
determining, in response to K/(N+N₁) being less than or equal to 130/512, that the threshold is equal to N; or
determining, in response to K/(N+N₁) being greater than 130/512, that the threshold is equal to └63/64×N┘.

18. The method of claim 13, wherein determining the second reliability subsequence comprises extracting, from the reliability sequence, the second reliability subsequence, and wherein N+N₁ subchannel indices corresponding to the second reliability subsequence comprise N subchannel indices corresponding to the first reliability subsequence and the N₁ subchannel indices in the subchannel set.

19. The method of claim 11, wherein determining the first information bit subchannel set comprises determining, based on the first reliability subsequence, first K subchannel indices with high reliability to obtain the first information bit subchannel set, wherein K is a positive integer indicating a quantity of bits to be encoded, wherein determining the second information bit subchannel set comprises determining, based on the reliability sequence, second K subchannel indices with high reliability that do not belong to the pre-frozen bit subchannel set to obtain the second information bit subchannel set, and wherein determining the corresponding first bit subchannel subset comprises:
obtaining, from the second information bit subchannel set, subchannel indices that are less than N as the second bit subchannel subset; and
determining, based on a quantity of elements in the second bit subchannel subset, a same quantity of subchannel indices with low reliability in the first information bit subchannel set to obtain the first bit subchannel subset.

20. An apparatus, comprising:
a memory configured to store instructions; and
one or more processors coupled to the memory and configured to execute the instructions to cause the apparatus to:
determine, based on a reliability sequence of length N₂, a pre-frozen bit subchannel set, wherein a quantity of elements in the pre-frozen bit subchannel set is greater than or equal to 0, and wherein N₂ is a positive integer;
determine, based on a first reliability subsequence of length N in the reliability sequence, a first information bit subchannel set, wherein N is a positive integer, and wherein N is less than N₂;
determine, based on the reliability sequence and the pre-frozen bit subchannel set, a second information bit subchannel set;
determine, based on a second bit subchannel subset in the second information bit subchannel set, a first bit subchannel subset in the first information bit subchannel set;
determine, based on the first bit subchannel subset and the second bit subchannel subset, a bit sequence; and
perform polar encoding on the bit sequence to obtain an encoded result.
